(19) United States
(12) Patent Application Publication
(10) Pub. No.: US 2025/0143141 A1
(43) Pub. Date: May 1, 2025

(54) DISPLAY DEVICE AND METHOD OF FABRICATING THE SAME

(71) Applicant: Samsung Display Co., Ltd., Yongin-Si (KR)

(72) Inventors: Woo Yong SUNG, Yongin-si (KR); Seung Yong SONG, Yongin-si (KR); Hee Jun YANG, Yongin-si (KR); Jeong Seok LEE, Yongin-si (KR)

(21) Appl. No.: 18/740,509

(22) Filed: Jun. 12, 2024

(30) Foreign Application Priority Data
Oct. 31, 2023 (KR) 10-2023-0147357

(51) Int. Cl. H10K 59/80; H10K 59/12; H10K 59/122

(52) U.S. Cl. CPC H10K 59/873; H10K 59/1201; H10K 59/122

(57) ABSTRACT

A display device includes a non-light emitting area between first and second light emitting portions; a first light emitting structure including a first display element on the first light emitting portion; a first thin film encapsulation layer on the first light emitting structure; and a second light emitting structure on the first thin film encapsulation layer and including a second display element overlapping the second light emitting portion. The first light emitting structure includes a first pixel defining layer defining a first opening and a bank structure on the first pixel defining layer and including first and second bank layers. The second bank layer includes a tip that protrudes toward the first light emitting portion more than a side surface of the first bank layer. The second display element overlaps the first pixel defining layer and contacts the second bank layer.

### CROSS-REFERENCE TO RELATED APPLICATION

This application claims priority from Korean Patent Application No. 10-2023-0147357 filed on Oct. 31, 2023 in the Korean Intellectual Property Office, and all the benefits accruing therefrom under 35 U.S.C. 119, the contents of which in its entirety are herein incorporated by reference.

### BACKGROUND

### Technical Field

The present disclosure relates to a display device and a method of fabricating the same.

### Description of the Related Art

Our current information society increasingly demands display devices for displaying images in various applications. For example, display devices have been applied to electronic devices such as smartphones, digital cameras, laptop computers, navigation devices, and smart televisions. The display devices may be flat panel display devices such as liquid crystal display devices, field emission display devices, or organic light emitting display devices. Among the flat panel display devices, a light emitting display device may include an array of pixels, and each of the pixels may include a light emitting element that may emit light, thereby allowing the display device to display an image without the need of a backlight unit providing the light to the display device.

The demand for display devices with high aperture ratio and high resolution is increasing. Since high pixel integration is required for display devices with high aperture ratio and high resolution, a display device that meets such requirements and a method of fabricating the display device may be required.

### SUMMARY

Aspects of the present disclosure provide a display device with high resolution and high aperture ratio and a method of fabricating the display device. However, aspects of the present disclosure are not restricted to those set forth herein. The above and other aspects of the present disclosure will become more apparent to one of ordinary skill in the art to which the present disclosure pertains by referencing the detailed description of embodiments of the present disclosure. Details of example embodiments are included in the detailed description and drawings.

A display device includes a substrate including a light emitting area including a first light emitting portion and a second light emitting portion and a non-light emitting area positioned between the first light emitting portion and the second light emitting portion; a first light emitting structure including a first display element positioned on the first light emitting portion of the substrate; a first thin film encapsulation layer on the first light emitting structure; and a second light emitting structure positioned on the first thin film encapsulation layer and including a second display element overlapping the second light emitting portion, wherein the first light emitting structure includes a first pixel defining layer defining a first opening; and a bank structure positioned on the first pixel defining layer and including a first bank layer and a second bank layer, the second bank layer includes a tip that protrudes more toward the first light emitting portion than a side surface of the first bank layer, and the second display element overlaps the first pixel defining layer in a direction perpendicular to the substrate, and is in contact with the second bank layer.

The first display element may include a first electrode; a first display light emitting layer on the first electrode; and a second electrode on the first display light emitting layer, the first display light emitting layer and the second electrode are in contact with the side surface of the first bank layer facing the first light emitting portion, and the second electrode is electrically connected to the first bank layer.

A display may further comprise a first organic pattern disposed on the second bank layer and surrounding the first opening; and a first electrode pattern disposed on the first organic pattern, wherein the first organic pattern includes the same material as the first electrode, and the first electrode pattern includes the same material as the second electrode.

The first organic pattern may be spaced apart from the first electrode, and the first electrode pattern may be spaced apart from the second electrode.

In a portion overlapping the non-light emitting area, a first pattern may be positioned between the first electrode and the first pixel defining layer in the direction perpendicular to the substrate, and the first pattern may be in contact with the first display light emitting layer.

The second light emitting structure may further include a second pixel defining layer overlapping the first light emitting portion and defining a second opening, and the second pixel defining layer overlaps the first display element in the direction perpendicular to the substrate.

The second display element may include a third electrode; a second display light emitting layer on the third electrode; and a common electrode on the second display light emitting layer and the second pixel defining layer.

The third electrode may be in contact with the second bank layer in a direction toward the substrate.

The first thin film encapsulation layer may include a first encapsulation layer in contact with the first display element and the bank structure; and a second encapsulation layer including an organic material on the first encapsulation layer, and the second encapsulation layer may be completely surrounded by the first encapsulation layer and the second pixel defining layer in a portion overlapping the first light emitting portion.

A display may further comprise in a portion overlapping the second light emitting portion, a monomer pattern on side surfaces of the third electrode in a direction parallel to the substrate, wherein the monomer pattern and the second encapsulation layer may include the same material.

The first encapsulation layer may be in contact with the protruding tip of the second bank layer.

In a portion overlapping the non-light emitting area, a second pattern may be positioned between the third electrode and the second pixel defining layer in the direction perpendicular to the substrate, and the second pattern may be in contact with the second display light emitting layer.

The first opening may define the first light emitting portion, and the second opening may define the second light emitting portion.

In plan view, the first pixel defining layer may have a mesh shape that completely surrounds the first light emitting portion, and in plan view, the second pixel defining layer may have a mesh shape that completely surrounds the second light emitting portion.

A display may further comprise a spacer disposed on the second pixel defining layer, wherein the spacer may overlap the third electrode in the direction perpendicular to the substrate.

A third pattern may be positioned between the spacer and the third electrode in the direction perpendicular to the substrate.

A display device includes a substrate including a first light emitting area including a first light emitting portion and a second light emitting portion, and a second light emitting area spaced apart from the second light emitting portion with the first light emitting portion interposed therebetween; a first light emitting structure positioned on the substrate and including a first light emitting element overlapping the first light emitting portion, a second light emitting element overlapping the second light emitting area, and a bank structure overlapping the second light emitting portion; a first encapsulation layer on the first light emitting structure; and a second light emitting structure positioned on the first encapsulation layer and including a third light emitting element overlapping the second light emitting portion, wherein the bank structure includes a first portion in contact with the first light emitting element, “second portion in contact with the third light emitting element, and a third portion in contact with the second light emitting element, and the first portion, the second portion, and the third portion are spaced apart from each other with the first encapsulation layer interposed therebetween.

The first encapsulation layer may include a first inorganic layer surrounding the first portion; and a second inorganic layer surrounding the third portion, and the first inorganic layer and the second inorganic layer may be spaced apart from each other with the second portion interposed in a direction parallel to the substrate.

A method of fabricating a display device, the method includes preparing a substrate including a light emitting area including a first light emitting portion and a second light emitting portion and a non-light emitting area positioned between the first light emitting portion and the second light emitting portion; forming a first electrode on the first light emitting portion of the substrate and a sacrificial layer on the first electrode, forming an auxiliary electrode spaced apart from the first electrode on the second light emitting portion of the substrate, and forming a first pixel defining layer covering a portion of the sacrificial layer and the auxiliary electrode; forming a first hole overlapping the first electrode by forming a first bank material layer completely covering the first electrode, the auxiliary electrode, and the first pixel defining layer, and a second bank material layer on the first bank material layer, and then removing a portion of the first bank material layer and the second bank material layer through an etching process; forming a first bank layer and a second bank layer including a tip protruding more toward the first light emitting portion than the first bank layer by partially etching the inside of the first hole through an etching process, and forming a second hole overlapping the first pixel defining layer; forming a first light emitting layer and a second electrode on the first electrode overlapping the first light emitting part to be in contact with a side surface of the first bank layer, and forming a first thin film encapsulation layer completely covering the first bank layer and the second bank layer; exposing a portion of the second bank layer overlapping the second light emitting portion by removing a portion of the first thin film encapsulation layer overlapping the second light emitting portion through an etching process; forming a third electrode on the second bank layer and the first thin film encapsulation layer and a sacrificial layer on the third electrode to overlap the second light emitting portion, and forming a second pixel defining layer overlapping the first light emitting portion, covering a portion of the sacrificial layer, and defining a second opening; removing the sacrificial layer on the third electrode through an etching process using the second pixel defining layer as a mask, forming a second light emitting layer on the third electrode, and then forming a common electrode entirely covering the second light emitting layer and the second pixel defining layer; and forming a second thin film encapsulation layer on the common electrode, wherein in the forming of the third electrode, the third electrode is in contact with the second bank layer.

In the forming of the first light emitting layer and the second electrode, a first organic pattern disposed on the second bank layer and a first electrode on the first organic pattern may be formed, the first organic pattern includes the same material as the first light emitting layer, and is spaced apart from the first light emitting layer, and the first electrode pattern includes the same material as the second electrode, and is spaced apart from the second electrode.

The display device according to an embodiment may include a first light emitting structure and a second light emitting structure that are vertically stacked. A first pixel defining layer included in the first light emitting structure may define a first opening, and a second pixel defining layer included in the second light emitting structure may define a second opening, and light emitted from the first opening and light emitted from the second opening may emit light of the same color.

The display device according to an may secure the maximum area of the light emitting area and the minimum area of the non-light emitting area by designing the first opening and the second opening in a direction perpendicular to the substrate so as not to overlap each other. Therefore, the display device according to an embodiment may be provided as a display device with a high aperture ratio and high resolution.

However, the effects of the embodiments are not restricted to the one set forth herein. The above and other effects of the embodiments will become more apparent to one of daily skill in the art to which the embodiments pertain by referencing the claims.

### BRIEF DESCRIPTION OF THE DRAWINGS

The above and other aspects and features of the present disclosure will become more apparent from example embodiments that are illustrated in the attached drawings as follows.

FIG. 1 is a perspective view illustrating an electronic device according to an embodiment.

FIG. 2 is a perspective view illustrating a display device included in the electronic device according to an embodiment.

FIG. 3 is a schematic cross-sectional view of the display device of FIG. 2.

FIG. 4 is a schematic plan view of an embodiment of a display layer shown in FIG. 3.

FIG. 5 is a plan view illustrating an arrangement of light emitting areas in an embodiment of a display area shown in FIG. 4.

FIG. 6 is a schematic cross-sectional view of the display area taken along line X1-X1′ of FIG. 5.

FIG. 7 is an enlarged cross-sectional view of a first light emitting portion of a first light emitting area shown in FIG. 6.

FIG. 8 is an enlarged cross-sectional view of a second light emitting portion of the first light emitting area shown in FIG. 6.

FIG. 9 is an enlarged cross-sectional view of a second light emitting portion of a second light emitting area overlapping a peripheral portion of a spacer in FIG. 6.

FIG. 10 is a plan view illustrating an arrangement of a first pixel defining layer and a second pixel defining layer in FIG. 6.

FIGS. 11, 12, 13, 14, 15, 16, 17, 18, 19, 20, 21, 22, 23, 24, 25, and 26 are cross-sectional views schematically illustrating structures formed during a method of fabricating an embodiment of a display element layer shown in FIG. 6.

### DETAILED DESCRIPTION OF THE EMBODIMENTS

Example embodiments in accordance with the present disclosure are described below with reference to the accompanying drawings. For simplicity and clarity of illustration, elements in the drawings are not necessarily drawn to scale. The same reference numbers in different drawings represent the same or similar elements and, as such, perform similar functionality. Further, descriptions and details of well-known steps and elements may be omitted below for simplicity of the description. Furthermore, in the following detailed description, numerous specific details are set forth in order to provide a thorough understanding of the disclosure. However, it will be understood that the disclosure may be practiced without these specific details. In other instances, well-known methods, procedures, components, and circuits have not been described in detail so as not to unnecessarily obscure aspects of the disclosure. The description provided herein is not intended to limit the claims to the specific embodiments described. On the contrary, it is intended to cover alternatives, modifications, and equivalents as may be included within the spirit and scope of the disclosure as defined by the appended claims.

A shape, a size, a percentage, an angle, a number, etc. shown in the drawings for describing embodiments of the disclosure are illustrative, and the disclosure is not limited thereto. Furthermore, in the following detailed description of the disclosure, numerous specific details are set forth in order to provide a thorough understanding of specific embodiments of the disclosure. However, it will be understood that the disclosure may be practiced without these specific details.

The terminology used herein is for the purpose of describing particular embodiments only and is not intended to limit the disclosure. As used herein, singular articles, e.g., “a” and “an”, and nouns are intended to include the plural form as well, unless the context clearly indicates otherwise. It will be further understood that the terms “comprises,” “comprising,” “includes,” and “including,” when used in this specification, specify the presence of the stated features, integers, operations, elements, and/or components, but do not preclude the presence or addition of one or more other features, integers, operations, elements, components, and/or portions thereof. As used herein, the terms “and/or” and “or” includes any and all combinations of one or more of the associated listed items. Expressions such as “at least one of” when preceding a list of elements may modify the entirety of list of elements and may not modify the individual elements of the list. When referring to “C to D”, this means C inclusive to D inclusive unless otherwise specified.

The terms “first”, “second”, “third”, and so on may be used herein to describe various elements, components, regions, layers and/or sections, but these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the disclosure.

An element or layer referred to herein as being “connected to”, or “coupled to” another element or layer, means that the element or layer may be directly on, connected to, or coupled to the other element or layer, or one or more intervening elements or layers may be between the elements or layers. In addition, when an element or layer is referred to as being “between” two elements or layers, it may be the only element or layer between the two elements or layers, or one or more intervening elements or layers may also be between the two elements or layers.

A layer, film, region, plate, or the like referred to herein as being disposed “on” or “on top” of another layer, film, region, plate, or the like means that the former may directly contact the latter or still another layer, film, region, plate, or the like may be disposed between the former and the latter. As used herein, when a layer, film, region, plate, or the like is directly disposed “on” or “on top” of another layer, film, region, plate, or the like, the former directly contacts the latter and still another layer, film, region, plate, or the like is not disposed between the former and the latter. Further, as used herein, when a layer, film, region, plate, or the like is disposed “below” or “under” another layer, film, region, plate, or the like, the former may directly contact the latter or still another layer, film, region, plate, or the like may be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

Unless otherwise defined, all terms including technical and scientific terms used herein have the same meaning as commonly understood by one of ordinary skill in the art to which this disclosure pertains. Terms, such as those defined in commonly used dictionaries, should be interpreted as having a meaning that is consistent with their meaning in the context of the relevant art and should not be interpreted in an idealized or overly formal sense unless expressly so defined herein.

The example embodiments disclosed herein may generally be implemented differently, and functions or operations specified in specific blocks or a sequential order may occur in a sequence different from that specified herein. For example, two blocks shown as consecutive in a flowchart may actually be executed at the same time. Also, depending on a related function or operation, the blocks may be executed in a reverse sequence.

In descriptions of temporal relationships, for example, where one event is indicated as being “after”, “subsequent to”, “before”, etc. another event, a further event may occur therebetween unless a temporal relationship such as “directly after”, “directly subsequent” or “directly before” is indicated.

The features of the various embodiments of the disclosure may be partially or entirely combined with each other and may be technically associated with each other or operate with each other. The embodiments may be implemented independently of each other or may be implemented together in an association relationship.

Spatially relative terms, such as “beneath,” “below,” “lower,” “under,” “above,” “upper,” and the like, may be used herein for ease of explanation to describe one element or feature's relationship to another element or feature as illustrated in the figures. The spatially relative terms are intended to encompass different orientations, in addition to the orientation depicted in the figures. For example, when a device in the drawings is turned over, elements described as “below” or “beneath” or “under” other elements or features would then be oriented “above” the other elements or features. Thus, the example terms “below” and “under” may encompass both an orientation of above and below depending on the orientation of the device. The device may be otherwise oriented for example, rotated 90 degrees or at other orientations, and the spatially relative descriptors used herein should be interpreted accordingly.

Specific embodiments are described below with reference to the accompanying drawings.

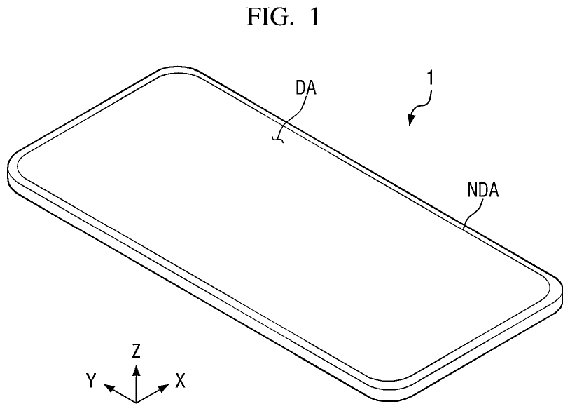

FIG. 1 is a schematic perspective view of an electronic device 1 according to an embodiment.

Referring to FIG. 1, the electronic device 1 may display a moving image or a still image. The electronic device 1 may be any electronic device that has a display screen. For example, electronic device 1 may be a television, laptop computer, monitor, billboard, Internet of things device, mobile phone, smartphone, tablet personal computer (PC), electronic watch, smartwatch, watch phone, head mounted display, mobile communication terminal, electronic notebook, electronic book, portable multimedia player (PMP), navigation system, game console, digital camera, camcorder, and the like that provides the display screen.

FIG. 1 defines a first direction (X-axis direction), a second direction (Y-axis direction), and a third direction (Z-axis direction). The first direction (X-axis direction) and the second direction (Y-axis direction) may be perpendicular to each other, the first direction (X-axis direction) and the third direction (Z-axis direction) may be perpendicular to each other, and the second direction (Y-axis direction) and the third direction (Z-axis direction) may be perpendicular to each other. As a convention used herein, the first direction (X-axis direction) is a horizontal direction in the drawings, the second direction (Y-axis direction) is a vertical direction in the drawings, and the third direction (Z-axis direction) is a direction from lower to upper device surfaces in the drawings, that is, a thickness direction. Unless otherwise specified, the term “direction” may refer to both positive and negative extension along the direction. In FIG. 1, a direction in which an arrow points is referred to as positive, and an opposite direction thereof is referred to as the negative.

FIG. 1 shows a main surface of the electronic device 1 that displays and image and that faces facing in the positive third direction (Z-axis direction). The surface that faces in the positive Z-axis direction is some referred to as one surface or an upper surface, and an opposite surface of the one surface is sometimes referred herein to as the other surface. However, the present disclosure is not limited thereto, and the one surface and the other surface of the electronic device 1 may be referred to as a front surface and a rear surface, respectively, or may also be referred to as a first surface or a second surface. In addition, in describing a relative position, a side of each element toward the positive Z-axis direction may be referred to as an upper side and the other side of the element (toward the negative Z-axis direction) may be referred to as a lower side.

A shape of the electronic device 1 may be variously changed. For example, the electronic device 1 may have a shape such as a rectangle with a long width, a rectangle with a long length, a square, a quadrangle with rounded corners (vertices), other polygons, or a circle.

The electronic device 1 may include a display area DA and a non-display area NDA. The display area DA is an area in which a screen may display an image, and the non-display area NDA is an area in which an image is not displayed. The display area DA may also be referred to as an active area, and the non-display area NDA may also be referred to as a non-active area. The display area DA may generally occupy the center of the upper surface of the electronic device 1.

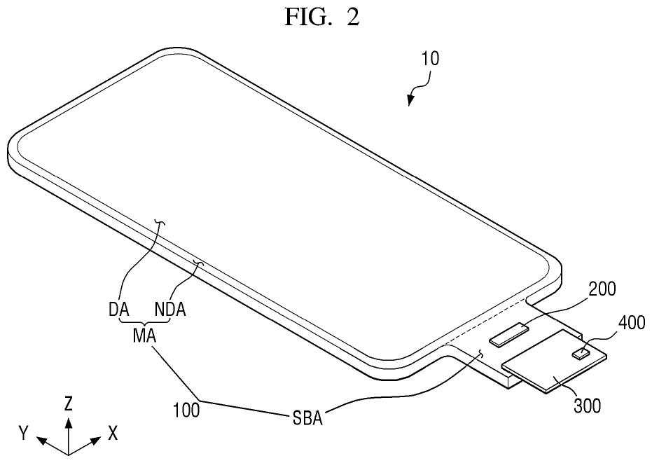

FIG. 2 is a perspective view illustrating an embodiment of a display device 10 that may be included in the electronic device 1 of FIG. 1.

Referring to FIGS. 1 and 2, the electronic device 1 according to an embodiment may include the display device 10. The display device 10 may provide a screen on which the electronic device 1 displays an image. Examples of the display device 10 may include an inorganic light emitting diode display device, an organic light emitting display device, a quantum dot light emitting display device, a plasma display device, and a field emission display device. Hereinafter, the following primarily describes an example in which the display device 10 is an organic light emitting diode display device is, but the present disclosure is not limited thereto and may also be applied to other display devices.

The display device 10 may have a planar shape similar to that of the electronic device 1. For example, the display device 10 may have a shape similar to a rectangle having a short side in a first direction (X-axis direction) and a long side in a second direction (Y-axis direction). A corner where the short side and the long side meet may be rounded to have a curvature, but the display device is not limited thereto and may have other planar shapes or corners formed at a right angle. The planar shape of the display device 10 is not limited to the quadrangle and may be similar to other polygons, circles, or ovals.

The display device 10 may include a display panel 100, a display driver 200, a circuit board 300, and a touch driver 400.

The display panel 100 may include a main area MA and a sub-area SBA. The main area MA may include a display area DA including pixels for displaying an image, and a non-display area NDA disposed around the display area DA.

The display area DA may emit light from a plurality of light emitting areas or a plurality of opening areas to be described below. For example, the display area DA may include a pixel circuit including switching elements, a pixel defining film defining the light emitting areas or the opening areas, and a light emitting element.

The non-display area NDA may be an area outside the display area DA. The non-display area NDA may be defined as an edge area of the main area MA of the display panel 100. The non-display area NDA may include a wiring driver that supplies signals to the display area DA and wiring connecting the display driver 200 and the display area DA.

The sub-area SBA may be an area extending from one side of the main area MA.

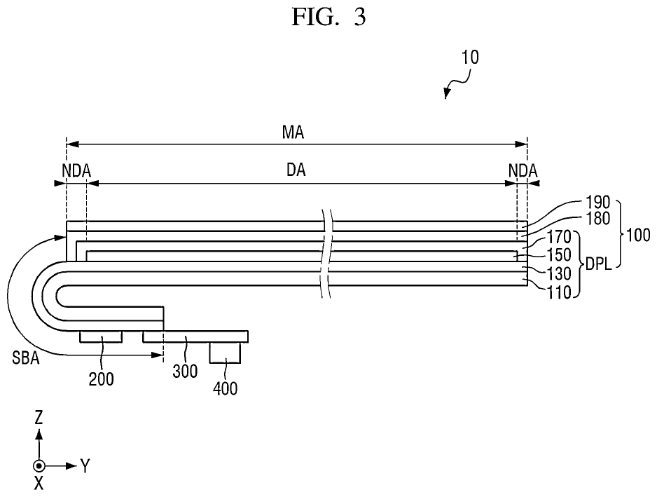

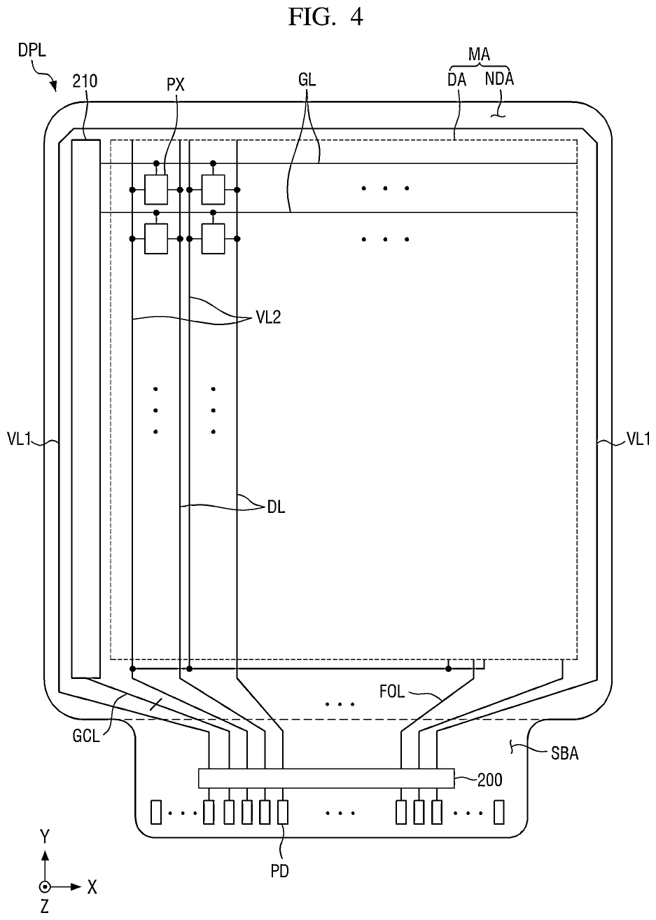

The sub-area SBA may include a flexible material that may be bent, folded, rolled, or the like. For example, when the sub-area SBA is bent as shown in FIG. 3, the sub-area SBA may overlap the main area MA in a thickness direction (e.g., the Z-axis direction). The sub-area SBA may include a display pad (“PD” in FIG. 4) connected to the display driver 200 and the circuit board 300. In another embodiment, the sub-area SBA may be omitted, and the display driver 200 and the display pad may be positioned in the non-display area NDA.

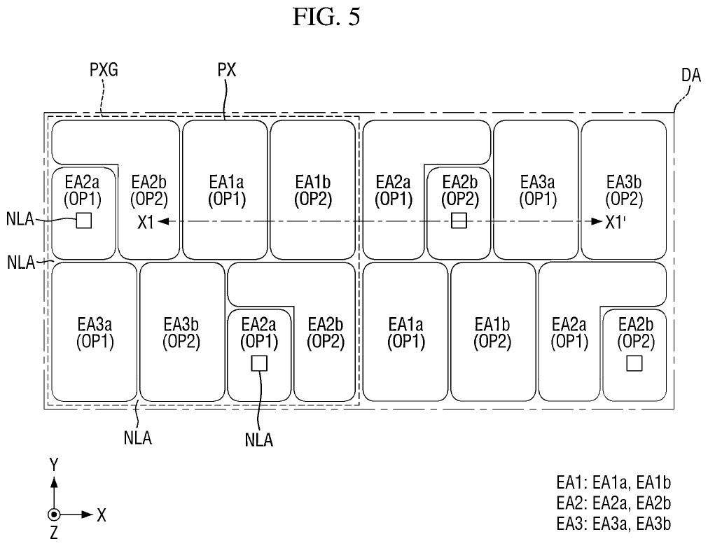

The display driver 200 may output signals and voltages for driving the display panel 100. The display driver 200 may supply data voltages to data lines (“DL” in FIG. 4), which are described below. In addition, the display driver 200 may supply a power voltage to power lines (“VL1 and VL2” in FIG. 4) and supply a gate control signal to gate driver (“210” in FIG. 5). The display driver 200 may be formed as an integrated circuit (IC) and mounted on the display panel 100 by a chip on glass (COG) method, a chip on plastic (COP) method, or an ultrasonic bonding method. For example, the display driver 200 may be disposed in the sub-area SBA and may overlap the main area MA in the thickness direction when the sub-area SBA is bent as shown in FIG. 3. As another example, the display driver 200 may be mounted on the circuit board 300.

The circuit board 300 may be attached onto the display pad of the display panel 100 using an anisotropic conductive film (ACF). The circuit board 300 may be electrically connected to the display pad. The circuit board 300 may be a flexible film such as a flexible printed circuit board, a printed circuit board, or a chip on film.

The touch driver 400 may be mounted on the circuit board 300. The touch driver 400 may be connected to a touch sensor layer (“180” in FIG. 3) of the display panel 100. FIG. 3 is a schematic cross-sectional view of the display device 10 of FIG. 2.

Referring to FIG. 3, the display panel 100 may include a display layer DPL, a touch sensor layer 180, and a color filter layer 190. The display layer DPL may include a substrate 110, a thin film transistor layer 130, a display element layer 150, and a thin film encapsulation layer 170.

The substrate 110 may be a base substrate or a base member. The substrate 110 may be a flexible substrate that may be bent, folded, rolled, or the like. For example, the substrate 110 may include a polymer resin such as polyimide (PI) but is not limited thereto. In another embodiment, the substrate 110 may include a glass material or a metal material.

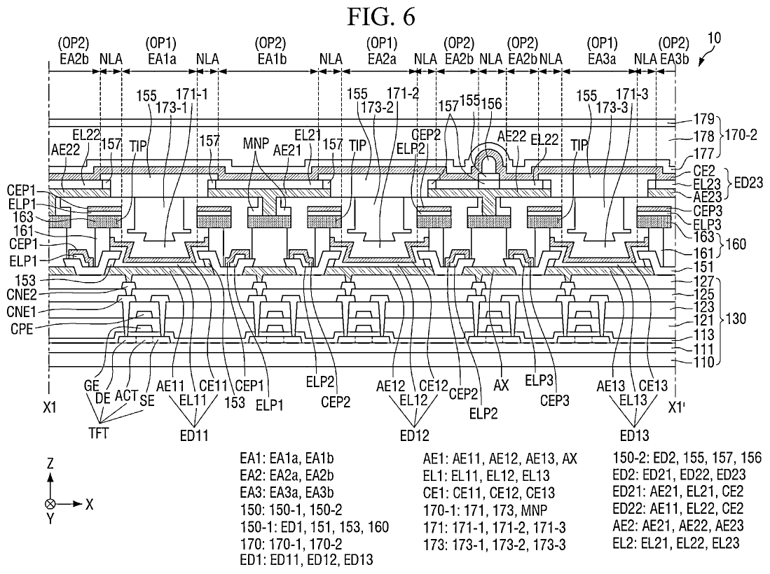

The thin film transistor layer 130 may be disposed on the substrate 110. The thin film transistor layer 130 may be disposed in the display area DA, the non-display area NDA, and the sub-area SBA. The thin film transistor layer 130 may include a plurality of thin film transistors (“TFT” in FIG. 6) constituting a pixel (“PX” in FIG. 4).

The display element layer 150 may be disposed on the thin film transistor layer 130. The display element layer 150 may be positioned to overlap the display area DA. The display element layer 150 may include a plurality of display elements (“ED1 and ED2” in FIG. 6). As an example, the display element according to an embodiment may include, but is not limited to, at least one of an organic light emitting diode (LED) including an organic light emitting layer, a quantum dot LED including a quantum dot light emitting layer, an inorganic LED including an inorganic semiconductor, and a micro LED.

The thin film encapsulation layer 170 may be positioned on the display element layer 150. The thin film encapsulation layer 170 may overlap the display area DA and the non-display area NDA. The thin film encapsulation layer 170 may cover an upper surface and side surfaces of the display element layer 150 and may protect the display element layer 150 from external oxygen and moisture. The thin film encapsulation layer 170 may include at least one inorganic film and at least one organic film for encapsulating the display element layer 150.

The touch sensor layer 180 may be disposed on the thin film encapsulation layer 170. The touch sensor layer 180 may be positioned to overlap the display area DA and the non-display area NDA. The touch sensor layer 180 may be used for a mutual capacitance method or a self-capacitance method for sensing a user's touch.

The color filter layer 190 may be disposed on the touch sensor layer 180. The color filter layer 190 may be positioned to overlap the display area DA and the non-display area NDA. The color filter layer 190 may absorb a portion of light introduced from the outside of the display device 10 to reduce reflected light caused by external light. Therefore, the color filter layer 190 may prevent color distortion caused by reflection of external light.

As the color filter layer 190 may be directly disposed on the touch sensor layer 180, the display device 10 may not require a separate substrate for the color filter layer 190. Therefore, the display device 10 may have a relatively small thickness. In addition, the color filter layer 190 may also be omitted depending on the embodiment.

As illustrated in FIG. 3, a portion of the display layer DPL overlapping the sub-area SBA may be bent. When a portion of the display layer DPL is bent, the display driver 200, circuit board 300, and touch driver 400 may overlap the main area MA in the third direction (Z-axis direction).

FIG. 4 is a schematic plan view illustrating an embodiment of the display layer DPL of FIG. 3.

Referring to FIG. 4, the display layer DPL according to an embodiment may include a plurality of pixels PX, a plurality of gate lines GL, a plurality of data lines DL, and a plurality of second power lines VL2 overlapping the display area DA of the main area MA.

Each of the plurality of pixels PX may be defined as a minimum unit emitting light of a controllable color or intensity. Each of the plurality of pixels PX may include first to third light emitting areas EA1, EA2, and EA3, which are described below.

The plurality of gate lines GL may supply to the plurality of pixels PX a gate signal received from a gate driver 210. The plurality of gate lines GL may extend in the first direction (X-axis direction) and may be spaced apart from each other in the second direction (Y-axis direction).

The plurality of data lines DL may supply the data voltages received from the display driver 200 to the plurality of pixels PX. The plurality of data lines DL may extend in the second direction (Y-axis direction) and may be spaced apart from each other in the first direction (X-axis direction).

The plurality of second power line VL2 may supply the power voltage received from the display driver 200 to the plurality of pixels PX. Here, the power voltage may be at least one of a driving voltage, an initialization voltage, and a reference voltage. The plurality of second power lines VL2 may extend in the second direction (Y-axis direction) and may be spaced apart from each other in the first direction (X-axis direction).

The display layer DPL according to an embodiment may include a first power line VL1, a gate driver 210, a plurality of fan-out lines FOL, and a gate control line GCL overlapping the non-display area NDA of the main area MA.

The gate driver 210 may generate a plurality of gate signals based on the gate control signal, and may sequentially supply the plurality of gate signals to the plurality of gate lines GL according to a set order.

The first power line VL1 may surround the display area DA and may be disposed in the non-display area NDA. The first power line VL1 may supply the power voltage received from the display driver 200 to the plurality of pixels PX. In addition, the first power line VL1 may be electrically connected to various wirings positioned in the display area DA.

The plurality of fan-out lines FOL may extend from the display driver 200 to the display area DA. The fan-out lines FOL may supply the data voltage received from the display driver 200 to the plurality of data lines DL.

The gate control line GCL may extend from the display driver 200 to the gate driver 210. The gate control line GCL may supply the gate control signal received from the display driver 200 to the gate driver 210. FIG. 4 shows the gate driver 210 in the non-display area NDA and only disposed on the left side of the display area DA, but the present disclosure is not limited thereto. In another embodiment, the display device 10 may also include a plurality of gate drivers 210 respectively disposed on the left and right sides of the display area DA.

The display layer DPL according to an embodiment may include a display driver 200 and a plurality of display pads PD overlapping the sub-area SBA.

The display driver 200 may output signals and voltages to the fan-out lines FOL for driving the plurality of pixels PX. The display driver 200 may supply the data voltage to the data lines DL through the plurality of fan-out lines FOL. As a result, the data voltage may be supplied to the plurality of pixels PX, and luminance and color of light emitted from the plurality of pixels PX may be controlled. In addition, the display driver 200 may supply the gate control signal to the gate driver 210 through the gate control line GCL.

The plurality of display pads PD may be connected to a graphic system through the circuit board 300. The plurality of display pads PD may be connected to the circuit board 300 to receive digital video data and supply the digital video data to the display driver 200.

FIG. 5 is a plan view illustrating an arrangement of light emitting areas in the display area DA of FIG. 4.

Referring to FIG. 5, the display area DA according to an embodiment may include first to third light emitting areas EA1, EA2, and EA3 and a non-light emitting area NLA.

The non-light emitting area NLA may include a portion that surrounds each of the first to third light emitting areas EA1, EA2, and EA3. This portion of the non-light emitting area NLA may assist in preventing mixing of the light emitted from the first to third light emitting areas EA1, EA2, and EA3.

The non-light emitting area NLA according to an embodiment may further include portions inside the second light emitting area EA2. A spacer (“156” in FIG. 6), which is described below, may be positioned in the non-light emitting area NLA disposed inside the second light emitting area EA2. FIG. 5 shows portions of the non-light emitting area NLA inside the second light emitting area EA2, but the present disclosure is not limited thereto. That is, the non-light emitting area NLA overlapping the spacer 156, which is described below, may be freely adjusted within the first to third light emitting areas EA1, EA2, and EA3 according to required characteristics of the display device 10.

The first to third light emitting areas EA1, EA2, and EA3 may each emit red, green, or blue light, and the color of light emitted from each of the first to third light emitting areas EA1, EA2, and EA3 may vary depending on the type of a first display element (“ED1” in FIG. 6) and a second display element (“ED2” in FIG. 6), which are described below.

The first light emitting area EA1 according to an embodiment may include a first light emitting portion EA1a and a second light emitting portion EA1b. In plan view, the first light emitting portion EA1a and the second light emitting portion EA1b may be spaced apart from each other with the non-light emitting area NLA interposed therebetween, and in plan view, each of the first light emitting portion EA1a and the second light emitting portion EA1b may be completely surrounded by the non-light emitting area NLA. The first light emitting portion EA1a and the second light emitting portion EA1b may emit the same color. As an example, the first light emitting portion EA1a and the second light emitting portion EA1b may emit red light. FIG. 5 shows an example in which the first light emitting portion EA1a and the second light emitting portion EA1b have the same size, but the present disclosure is not limited thereto. That is, the size (or area) and shape of the first light emitting portion EA1a and the second light emitting portion EA1b may be freely adjusted according to required characteristics.

The second light emitting area EA2 according to an embodiment may include a first light emitting portion EA2a and a second light emitting portion EA2b. In plan view, the first light emitting portion EA2a and the second light emitting portion EA2b may be spaced apart from each other with the non-light emitting area NLA interposed therebetween, and in plan view, each of the first light emitting portion EA2a and the second light emitting portion EA2b may be completely surrounded by the non-light emitting area NLA. The first light emitting portion EA2a and the second light emitting portion EA2b may emit the same color. As an example, the first light emitting portion EA2a and the second light emitting portion EA2b may emit green light. FIG. 5 shows an example in which the size of the first light emitting portion EA2a is smaller than the size of the second light emitting portion EA2b, but the present disclosure is not limited thereto. That is, the size (or area) and shape of the first light emitting portion EA2a and the second light emitting portion EA2b may be freely adjusted according to required characteristics.

The third light emitting area EA3 according to an embodiment may include a first light emitting portion EA3a and a second light emitting portion EA3b. In plan view, the first light emitting portion EA3a and the second light emitting portion EA3b may be spaced apart from each other with the non-light emitting area NLA interposed therebetween, and in plan view, each of the first light emitting portion EA3a and the second light emitting portion EA3b may be completely surrounded by the non-light emitting area NLA. The first light emitting portion EA3a and the second light emitting portion EA3b may emit the same color. As an example, the first light emitting portion EA3a and the second light emitting portion EA3b may emit blue light. FIG. 5 shows an example in which the first light emitting portion EA3a and the second light emitting portion EA3b have the same size, but the present disclosure is not limited thereto. That is, the size (or area) and shape of the first light emitting portion EA3a and the second light emitting portion EA3b may be freely adjusted according to required characteristics.

A pixel group PXG may include at least one first light emitting area EA1, at least two second light emitting areas EA2, and at least one third light emitting area EA3 disposed to be adjacent to each other. The pixel group PXG or an individual pixel PX may be a minimum unit used to emit white light. However, the type and/or number of light emitting areas EA1, EA2, and EA3 constituting a pixel group PXG may be variously changed according to the embodiment.

FIG. 6 is a schematic cross-sectional view of the display area DA taken along line X1-X1′ of FIG. 5. FIG. 6 particularly shows a partial cross-sectional view of the display device 10 overlapping the display area DA and illustrates a cross section of the substrate 110, the thin film transistor layer 130, the display element layer 150, and the thin film encapsulation layer 170. Since the substrate 110 was described with reference to FIG. 3, a description thereof will be omitted.

Referring to FIG. 6, the thin film transistor layer 130 may be positioned on the substrate 110. The thin film transistor layer 130 may include a first buffer layer 111, thin film transistors TFT, a gate insulating layer 113, a first interlayer insulating layer 121, a capacitor electrode CPE, a second interlayer insulating layer 123, a first connection electrode CNE1, a first via layer 125, a second connection electrode CNE2, and a second via layer 127.

The first buffer layer 111 may be disposed on the substrate 110. The first buffer layer 111 may include an inorganic film capable of preventing permeation of air or moisture. For example, the first buffer layer 111 may include a plurality of inorganic films alternately stacked.

The thin film transistors TFT may be disposed on the first buffer layer 111 and may constitute of a pixel circuit of each of the plurality of pixels. As an example, each thin film transistor TFT may be a driving transistor or a switching transistor of the pixel circuit. Each thin film transistor TFT may include an active layer ACT, a source electrode SE, a drain electrode DE, and a gate electrode GE.

The active layer ACT may be disposed on the first buffer layer 111. The active layer ACT may overlap the gate electrode GE in the third direction (Z-axis direction) and may be insulated from the gate electrode GE by the gate insulating layer 113. In a portion of the active layer ACT, a material of the active layer ACT may become a conductor to form the source electrode SE and the drain electrode DE.

The gate electrode GE may be disposed on the gate insulating layer 113. The gate electrode GE may overlap the active layer ACT with the gate insulating layer 113 interposed therebetween.

The gate insulating layer 113 may be disposed on the active layer ACT. For example, the gate insulating layer 113 may cover the active layer ACT and the first buffer layer 111 and may insulate the active layer ACT and the gate electrode GE from each other.

The gate insulating layer 113 may include a contact hole through which the first connection electrode CNE1 penetrates.

The first interlayer insulating layer 121 may cover the gate electrode GE and the gate insulating layer 113. The first interlayer insulating layer 121 may include a contact hole through which the first connection electrode CNE1 penetrates. The contact hole of the first interlayer insulating layer 121 may be connected to the contact hole of the gate insulating layer 113 and a contact hole of the second interlayer insulating layer 123.

The capacitor electrode CPE may be disposed on the first interlayer insulating layer 121. The capacitor electrode CPE may overlap the gate electrode GE in the third direction (Z-axis direction). The capacitor electrode CPE and the gate electrode GE may form a capacitor.

The second interlayer insulating layer 123 may cover the capacitor electrode CPE and the first interlayer insulating layer 121. The second interlayer insulating layer 123 may include a contact hole through which the first connection electrode CNE1 penetrates. The contact hole of the second interlayer insulating layer 123 may be connected to the contact hole of the first interlayer insulating layer 121 and the contact hole of the gate insulating layer 113.

The first connection electrode CNE1 may be disposed on the second interlayer insulating layer 123. The first connection electrode CNE1 may electrically connect the drain electrode DE of the thin film transistor TFT and the second connection electrode CNE2 to each other. The first connection electrode CNE1 may extend into the contact holes formed in the first interlayer insulating layer 121, the second interlayer insulating layer 123, and the gate insulating layer 113 and be in contact with the drain electrode DE of the corresponding thin film transistor TFT.

The first via layer 125 may cover the first connection electrode CNE1 and the second interlayer insulating layer 123. The first via layer 125 may provide planarized surface above contours of a lower structure. The first via layer 125 may include a contact hole through which the second connection electrode CNE2 penetrates.

The second connection electrode CNE2 may be disposed on the first via layer 125. The second connection electrode CNE2 may extend into the contact hole formed in the first via layer 125 and be in contact with the first connection electrode CNE1. The second connection electrode CNE2 may electrically connect the first connection electrode CNE1 and a first electrode AE1 to each other.

The second via layer 127 may cover the second connection electrode CNE2 and the first via layer 125. The second via layer 127 may include a contact hole through which the first electrode AE1 penetrates.

The display element layer 150 may be disposed on the thin film transistor layer 130. The display element layer 150 according to an embodiment may include a first light emitting structure 150-1 and a second light emitting structure 150-2. The first light emitting structure 150-1 and the second light emitting structure 150-2 may be sequentially stacked in the third direction (Z-axis direction). The display device 10 according to an embodiment may maximize the area of the light emitting area and minimize the area of the non-light emitting area by including the first light emitting structure 150-1 and the second light emitting structure 150-2 including different light emitting portions. Therefore, the display device 10 according to an embodiment may have features of high aperture ratio and high resolution.

The first light emitting structure 150-1 may be positioned on the second via layer 127. The first light emitting structure 150-1 may include a first display element ED1, a first pixel defining layer 151, a residual pattern 153, and a bank structure 160.

The first display element ED1 may be positioned on the second via layer 127. The first display element ED1 according to an embodiment may include a first light emitting element ED11 overlapping the first light emitting portion EA1a of the first light emitting area EA1, a second light emitting element ED12 overlapping the first light emitting portion EA2a of the second light emitting area EA2, and a third light emitting element ED13 overlapping the first light emitting portion EA3a of the third light emitting area EA3. The first display element ED1 may include a first electrode AE1, a first display light emitting layer EL1, and a second electrode CE1. As an example, the first light emitting element ED11 according to an embodiment may include a first anode electrode AE11, a first light emitting layer EL11, and a first cathode electrode CE11, the second light emitting element ED12 may include a second anode electrode AE12, a second light emitting layer EL12, and a second cathode electrode CE12, and the third light emitting element ED13 may include a third anode electrode AE13, a third light emitting layer EL13, and a third cathode electrode CE13.

In some embodiments, the first light emitting element ED11, the second light emitting element ED12, and the third light emitting element ED13 may emit light of different colors. As an example, the first light emitting element ED11 may emit red light of a first color, the second light emitting element ED12 may emit green light of a second color, and the third light emitting element ED13 may emit blue light of a third color.

The first electrode AE1 may be disposed on the second via layer 127. The first electrode AE1 according to an embodiment may be electrically connected to the drain electrode DE of the thin film transistor TFT through the first connection electrode CNE1 and the second connection electrode CNE2.

As an example, the first electrode AE1 may have a stacked film structure in which a material layer having a high work function, made of indium tin oxide (ITO), indium zinc oxide (IZO), zinc oxide (ZnO), or indium oxide (In₂O₃) and a reflective material layer made of silver (Ag), magnesium (Mg), aluminum (Al), platinum (Pt), lead (Pd), palladium (Pd), gold (Au), nickel (Ni), neodymium (Nd), iridium (Ir), chromium (Cr), lithium (Li), calcium (Ca), or mixtures thereof are stacked. As an example, the first electrode AE1 may have a multilayer structure of ITO/Mg, ITO/MgF, ITO/Ag, and ITO/Ag/ITO, but is not limited thereto.

The first electrode AE1 according to an embodiment may include a first anode electrode AE11, a second anode electrode AE12, a third anode electrode AE13, and an auxiliary electrode AX. Specifically, the first anode electrode AE11 may be disposed in a portion overlapping the first light emitting portion EA1a of the first light emitting area EA1, the second anode electrode AE12 may be disposed in a portion overlapping the first light emitting portion EA2a of the second light emitting area EA2, and the third anode electrode AE13 may be disposed in a portion overlapping the first light emitting portion EA3a of the third light emitting area EA3.

In addition, the auxiliary electrode AX may be disposed in portions overlapping the second light emitting portion EA1b of the first light emitting area EA1, the second light emitting portion EA2b of the second light emitting area EA2, and the second light emitting portion EA3b of the third light emitting area EA3, and the auxiliary electrode AX may be disposed to be spaced apart from each of the first to third anode electrodes AE11, AE12, and AE13. The auxiliary electrode AX according to an embodiment may be electrically connected to a third electrode AE2 (described below) through the first bank layer 161 and the second bank layer 163.

The first pixel defining layer 151 may be disposed on the second via layer 127 and the first electrode AE1. The plurality of first pixel defining layers 151 may overlap and be spaced apart from each of the first to third light emitting areas EA1, EA2, and EA3. The first pixel defining layer 151 according to an embodiment may include a first opening OP1 defining the first light emitting portion EA1a of the first light emitting area EA1, the first light emitting portion EA2a of the second light emitting area EA2, and the first light emitting portion EA3a of the third light emitting area EA3. The first opening OP1 may overlap each of the first to third light emitting areas EA1, EA2, and EA3 to expose the first to third anode electrodes AE11, AE12, and AE13. In other words, the first light emitting portion EA1a of the first light emitting area EA1, the first light emitting portion EA2a of the second light emitting area EA2, and the first light emitting portion EA3a of the third light emitting area EA3 may be defined by the first pixel defining layer 151.

The first pixel defining layer 151 may include an inorganic insulating material. As an example, the first pixel defining layer 151 may include aluminum oxide, titanium oxide, tantalum oxide, hafnium oxide, zinc oxide, silicon oxide, silicon nitride, and silicon oxynitride.

The bank structure 160 may be positioned on the first pixel defining layer 151. The bank structure 160 may include a first bank layer 161 and a second bank layer 163 that include different metal materials and perform different functions. The second bank layer 163 may have a tip TIP that protrudes more in the first direction (X-axis direction) than the first bank layer 161 toward the first light emitting portion EA1a of the first light emitting area EA1, the first light emitting portion EA2a of the second light emitting area EA2, and the first light emitting portion EA3a of the third light emitting area EA3.

The first display light emitting layer EL1 may be disposed on the first to third anode electrodes AE11, AE12, and AE13. The first display light emitting layer EL1 may be an organic light emitting layer made of an organic material and may be formed on the first to third anode electrodes AE11, AE12, and AE13 through a deposition process and a photo pattern process during fabrication of the display device 10. In the first display light emitting layer EL1, when the thin film transistor TFT applies a predetermined voltage to the first to third anode electrodes AE11, AE12, and AE13 and the second electrode CE1 receives a cathode voltage, holes and electrons may each move to the first display light emitting layer EL1 through a hole transporting layer and an electron transporting layer and may combine with each other in the first display light emitting layer EL1 to emit light.

The first display element ED1 according to an embodiment may include a first light emitting layer EL11 overlapping the first light emitting portion EA1a of the first light emitting area EA1, a second light emitting layer EL12 overlapping the first light emitting portion EA2a of the second light emitting area EA2, and a third light emitting layer EL13 overlapping the first light emitting portion EA3a of the third light emitting area EA3. The first display light emitting layer EL1 according to an embodiment may emit light of different colors depending on the materials included in the first light emitting layer EL11, the second light emitting layer EL12, and the third light emitting layer EL13. As an example, the first light emitting layer EL11 may emit red light of a first color, the second light emitting layer EL12 may emit green light of a second color, and the third light emitting layer EL13 may emit blue light of a third color, but the present disclosure is not limited thereto. In other words, the first display light emitting layers EL1 may be disposed to be spaced apart from each other at portions overlapping the first to third light emitting areas EA1, EA2, and EA3, and may be in contact with the first bank layer 161 at a portion overlapping the non-light emitting area NLA.

In some embodiments, the residual pattern 153 may be disposed between the first electrode AE1 and the first pixel defining layer 151 in the third direction (Z-axis direction) in the portion overlapping the non-light emitting area NLA. The residual pattern 153 is described below.

The second electrode CE1 may be disposed on the first display light emitting layer EL1. The second electrode CE1 may include a transparent conductive material so that light generated in the first display light emitting layer EL1 may be emitted. The second electrode CE1 may receive a common voltage or a low potential voltage. For example, when the first electrode AE1 receives a voltage corresponding to the data voltage and the second electrode CE1 receives a low potential voltage, the first display light emitting layer EL1 may emit light as a potential difference is formed between the first electrode AE1 and the second electrode CE1.

In an embodiment, the second electrode CE1 may include a material layer having a small work function, such as Li, Ca, LiF/Ca, LiF/Al, Al, Mg, Ag, Pt, Pd, Ni, Au, Nd, Ir, Cr, BaF, Ba, or compounds or mixtures thereof (e.g., a mixture of Ag and Mg, etc.). The second electrode CE1 may further include a transparent metal oxide layer disposed on the material layer having the small work function.

The second electrode CE1 according to an embodiment may include a first cathode electrode CE11 overlapping the first light emitting portion EA1a of the first light emitting area EA1, a second cathode electrode CE12 overlapping the first light emitting portion EA2a of the second light emitting area EA2, and a third cathode electrode CE13 overlapping the first light emitting portion EA3a of the third light emitting area EA3. The first cathode electrode CE11 may be positioned on the first light emitting layer EL11, may completely cover the first light emitting layer EL11, and may be in contact with the first bank layer 161. In addition, the second cathode electrode CE12 may be positioned on the second light emitting layer EL12, may completely cover the second light emitting layer EL12, and may be in contact with the first bank layer 161. In addition, the third cathode electrode CE13 may be positioned on the third light emitting layer EL13, may completely cover the third light emitting layer EL13, and may be in contact with the first bank layer 161. In other words, the second electrodes CE1 according to an embodiment may be disposed to be spaced apart from each other at the portions overlapping the first to third light emitting areas EA1, EA2, and EA3, and may be electrically connected through the first bank layer 161.

The display device 10 according to an embodiment may include first to third organic patterns ELP1, ELP2, and ELP3 and first to third electrode patterns CEP1, CEP2, and CEP3. The first to third organic patterns ELP1, ELP2, and ELP3 and the first to third electrode patterns CEP1, CEP2, and CEP3 may be positioned on the second bank layer 163 and the first pixel defining layer 151. The first to third organic patterns ELP1, ELP2, and ELP3 may each include the same material as the first to third light emitting layers EL11, EL12, and EL13, and the first to third electrode patterns CEP1, CEP2, and CEP3 may each include the same material as the first to third cathode electrodes CE11, CE12, and CE13. An arrangement relationship between the first to third electrode patterns CEP1, CEP2, and CEP3 and the first to third organic patterns ELP1, ELP2, and ELP3 may be the same as the arrangement relationship between the first display light emitting layer EL1 and the second electrode CE1.

The thin film encapsulation layer 170 according to an embodiment may include a first thin film encapsulation layer 170-1 and a second thin film encapsulation layer 170-2. The first thin film encapsulation layer 170-1 may include a first encapsulation layer 171, a second encapsulation layer 173, and a monomer pattern MNP. The second thin film encapsulation layer 170-2 is described below.

The first encapsulation layer 171 may be positioned on the bank structure 160 and the first display element ED1. The first encapsulation layer 171 may cover the bank structure 160 and the first display element ED1 along a profile formed by the bank structure 160 and the first display element ED1. That is, the first encapsulation layer 171 may have a level difference depending on a lower structure that the first encapsulation layer 171 covers.

The first encapsulation layer 171 may include a first inorganic layer 171-1, a second inorganic layer 171-2, and a third inorganic layer 171-3 that are positioned to overlap the first to third light emitting areas EA1, EA2, and EA3, respectively. The first inorganic layer 171-1, the second inorganic layer 171-2, and the third inorganic layer 171-3 may be spaced apart from each other in the first direction (X-axis direction) with the bank structure 160 and the third electrode AE2 interposed therebetween.

The first encapsulation layer 171 may include an inorganic material and may prevent oxygen or moisture from permeating into the first light emitting structure 150-1. As an example, the first encapsulation layer 171 may include aluminum oxide (Al₂O₃), titanium oxide (Ti₂O₃), tantalum oxide (Ta₂O₅), hafnium oxide (HfO₂), zinc oxide (ZnO), silicon oxide (SiO₂), silicon nitride (Si₃N₄), and silicon oxynitride (Si₂N₂O).

The second encapsulation layer 173 may be positioned on the first encapsulation layer 171. The second encapsulation layer 173 may overlap the first light emitting portion EA1a of the first light emitting area EA1, the first light emitting portion EA2a of the second light emitting area EA2, and the first light emitting portion EA2a of the third light emitting area EA3, and the second encapsulation layer 173 may not overlap the second light emitting portion EA1b of the first light emitting area EA1, the second light emitting portion EA2b of the second light emitting area EA2, and the second light emitting portion EA3b of the third light emitting area EA3.

The second encapsulation layer 173 may include a first organic layer 173-1 overlapping the first light emitting portion EA1a of the first light emitting area EA1, a second organic layer 173-2 overlapping the first light emitting portion EA2a of the second light emitting area EA2, and a third organic layer 173-3 overlapping the first light emitting portion EA3a of the third light emitting area EA3. The first inorganic layer 173-1, the second inorganic layer 173-2, and the third inorganic layer 173-3 may be spaced apart from each other in the first direction (X-axis direction) with the first encapsulation layer 171 and the bank structure 160 interposed therebetween.

The monomer pattern MNP may be disposed to be in contact with the second bank layer 163 and the third electrode AE2 at portions overlapping the second light emitting portion EA1b of the first light emitting area EA1, the second light emitting portion EA2b of the second light emitting area EA2, and the second light emitting portion EA3b of the third light emitting area EA3. The monomer pattern MNP and the second encapsulation layer 173 may include the same material.

The second encapsulation layer 173 may include an organic material and may protect the first light emitting structure 150-1 from foreign substances such as dust. In addition, the second encapsulation layer 173 may planarize the level difference formed by the first encapsulation layer 171. As an example, the second encapsulation layer 173 may include a silicon-based resin, an acrylic-based resin, an epoxy-based resin, and a mixture thereof.

The second light emitting structure 150-2 may be positioned on the first thin film encapsulation layer 170-1 and the second bank layer 163. The second light emitting structure 150-2 may include a second display element ED2, a second pixel defining layer 155, a spacer 156, and a residual pattern 157.

The second pixel defining layer 155 may be disposed on the first thin film encapsulation layer 170-1. A plurality of regions of the second pixel defining layer 155 may overlap and be spaced apart from each of the first to third light emitting areas EA1, EA2, and EA3. Specifically, the regions of the second pixel defining layer 155 may be disposed at the portions overlapping the first light emitting portion EA1a of the first light emitting area EA1, the first light emitting portion EA2a of the second light emitting area EA2, and the first light emitting portion EA3a of the third light emitting area EA3.

The second pixel defining layer 155 according to an embodiment may include a second opening OP2 defining the second light emitting portion EA1b of the first light emitting area EA1, the second light emitting portion EA2b of the second light emitting area EA2, and the second light emitting portion EA3b of the third light emitting area EA3. The second opening OP2 may overlap each of the first to third light emitting areas EA1, EA2, and EA3 to expose the third electrode AE2. In other words, the second light emitting portion EA1b of the first light emitting area EA1, the second light emitting portion EA2b of the second light emitting area EA2, and the second light emitting portion EA3b of the third light emitting area EA3 may be defined by the second pixel defining layer 155.

The second pixel defining layer 155 according to an embodiment may include a transparent inorganic insulating material. As an example, the second pixel defining layer 155 may include aluminum oxide, titanium oxide, tantalum oxide, hafnium oxide, zinc oxide, silicon oxide, silicon nitride, and silicon oxynitride. Therefore, the second pixel defining layer 155 according to an embodiment may transmit light emitted from the first display element ED1 even when being disposed to overlap the first display element ED1 in the third direction (Z-axis direction).

The second display element ED2 may be disposed on the second bank layer 163 and the first thin film encapsulation layer 170-1. The second display element ED2 according to an embodiment may include a first light emitting element ED21 overlapping the second light emitting portion EA1b of the first light emitting area EA1, a second light emitting element ED22 overlapping the second light emitting portion EA2b of the second light emitting area EA2, and a third light emitting element ED23 overlapping the second light emitting portion EA3b of the third light emitting area EA3. The second display element ED2 may include the third electrode AE2, a second display light emitting layer EL2, and a common electrode CE2. As an example, the first light emitting element ED11 according to an embodiment may include a first anode electrode AE21, a first light emitting layer EL21, and the common electrode CE2, the second light emitting element ED22 may include a second anode electrode AE22, a second light emitting layer EL22, and the common electrode CE2, and the third light emitting element ED23 may include a third anode electrode AE23, a third light emitting layer EL23, and the common electrode CE2.

In some embodiments, the first light emitting element ED21, the second light emitting element ED22, and the third light emitting element ED23 may emit light of different colors. As an example, the first light emitting element ED21 may emit red light of a first color, the second light emitting element ED22 may emit green light of a second color, and the third light emitting element ED23 may emit blue light of a third color.

The third electrode AE2 may be disposed on the second bank layer 163 and the first encapsulation layer 171. The third electrode AE2 may be in contact with the second bank layer 163 and the first encapsulation layer 171. The third electrode AE2 according to an embodiment may be electrically connected to the second bank layer 163, the first bank layer 161, and the auxiliary electrode AX in the third direction (Z-axis direction).

As an example, the third electrode AE2 may have a stacked film structure in which a material layer having a high work function, made of indium tin oxide (ITO), indium zinc oxide (IZO), zinc oxide (ZnO), or indium oxide (In₂O₃) and a reflective material layer made of silver (Ag), magnesium (Mg), aluminum (Al), platinum (Pt), lead (Pd), palladium (Pd), gold (Au), nickel (Ni), neodymium (Nd), iridium (Ir), chromium (Cr), lithium (Li), calcium (Ca), or mixtures thereof are stacked. As an example, the third electrode AE2 may have a multilayer structure of ITO/Mg, ITO/MgF, ITO/Ag, and ITO/Ag/ITO, but is not limited thereto.

The third electrode AE2 according to an embodiment may include a first anode electrode AE21 overlapping the second light emitting portion EA1b of the first light emitting area EA1, a second anode electrode AE22 overlapping the second light emitting portion EA2b of the second light emitting area EA2, and a third anode electrode AE23 overlapping the second light emitting portion EA3b of the third light emitting area EA3.

The first anode electrode AE21, the second anode electrode AE22, and the third anode electrode AE23 may be disposed to be spaced apart from each other in the first direction (X-axis direction) by the second pixel defining layer 155.

The second display light emitting layer EL2 may be disposed on the third electrode AE2. The second display light emitting layer EL2 may be an organic light emitting layer made of an organic material and may be formed on the third electrode AE2 through a deposition process during the fabricating process. In the second display light emitting layer EL2, when the thin film transistor TFT applies a predetermined voltage to the third electrode AE2 and the common electrode CE2 receives a common voltage, holes and electrons may each move to the second display light emitting layer EL2 through a hole transporting layer and an electron transporting layer, and may combine with each other in the second display light emitting layer EL2 to emit light.

The second display light emitting layer EL2 according to an embodiment may include a first light emitting layer EL21 overlapping the second light emitting portion EA1b of the first light emitting area EA1, a second light emitting layer EL22 overlapping the second light emitting portion EA2b of the second light emitting area EA2, and a third light emitting layer EL23 overlapping the second light emitting portion EA3b of the third light emitting area EA3. The second display light emitting layer EL2 according to an embodiment may emit light of different colors depending on the materials included in the first light emitting layer EL21, the second light emitting layer EL22, and the third light emitting layer EL23. As an example, the first light emitting layer EL21 may emit red light of a first color, the second light emitting layer EL22 may emit green light of a second color, and the third light emitting layer EL23 may emit blue light of a third color, but the present disclosure is not limited thereto.

In some embodiments, the residual pattern 157 may be disposed between the third electrode AE2 and the second pixel defining layer 155 in the third direction (Z-axis direction) in the portion overlapping the non-light emitting area NLA. The residual pattern 157 is described below.

The spacer 156 may be disposed in a portion overlapping the non-light emitting area NLA. The spacer 156 may be disposed in a portion overlapping the third electrode AE2 and the residual pattern 157. The display device 10 according to an embodiment may use a fine metal mask in the fabricating process of the second display light emitting layer EL2. In this case, the spacer 156 may assist in preventing the lower structure from being damaged by the fine metal mask.

The common electrode CE2 may be disposed on the entirety of the second display light emitting layer EL2 and the second pixel defining layer 155. In other words, the common electrode CE2 may be a common layer disposed in a portion overlapping the first to third light emitting areas EA1, EA2, and EA3 and the non-light emitting area NLA. The common electrode CE2 may completely cover the second display light emitting layer EL2, the second pixel defining layer 155, and the spacer 156. The common electrode CE2 may include a transparent conductive material so that light generated in the second display light emitting layer EL2 may be emitted.

In an embodiment, the common electrode CE2 may include a material layer having a small work function, such as Li, Ca, LiF/Ca, LiF/Al, Al, Mg, Ag, Pt, Pd, Ni, Au, Nd, Ir, Cr, BaF, Ba, or a compound or mixture thereof (e.g., a mixture of Ag and Mg, etc.). The common electrode CE2 may further include a transparent metal oxide layer disposed on the material layer having the small work function.

The second thin film encapsulation layer 170-2 may be disposed on the second light emitting structure 150-2. The second thin film encapsulation layer 170-2 may include a first encapsulation layer 177, a second encapsulation layer 178, and a third encapsulation layer 179.

The first encapsulation layer 177 may be disposed on the entirety of the common electrode CE2. The first encapsulation layer 177 may include an inorganic material and may completely cover the common electrode CE2. The first encapsulation layer 177 may prevent oxygen or moisture from permeating into the second light emitting structure 150-2. In addition, the second encapsulation layer 178 may be disposed on the entirety of the first encapsulation layer 177. The second encapsulation layer 178 may protect the second light emitting structure 150-2 from foreign substances such as dust and may planarize the level difference formed by the first encapsulation layer 177. In addition, the third encapsulation layer 179 may be disposed on the entirety of the second encapsulation layer 178. The third encapsulation layer 179 may include an inorganic material and may completely cover the second encapsulation layer 178.

As an example, the first encapsulation layer 177 and the third encapsulation layer 179 may include any one of aluminum oxide (Al₂O₃), titanium oxide (Ti₂O₃), tantalum oxide (Ta₂O₅), hafnium oxide (HfO₂), zinc oxide (ZnO), silicon oxide (SiO₂), silicon nitride (Si₃N₄), and silicon oxynitride (Si₂N₂O). In addition, the second encapsulation layer 178 may include a silicon-based resin, an acrylic-based resin, an epoxy-based resin, and a mixture thereof.

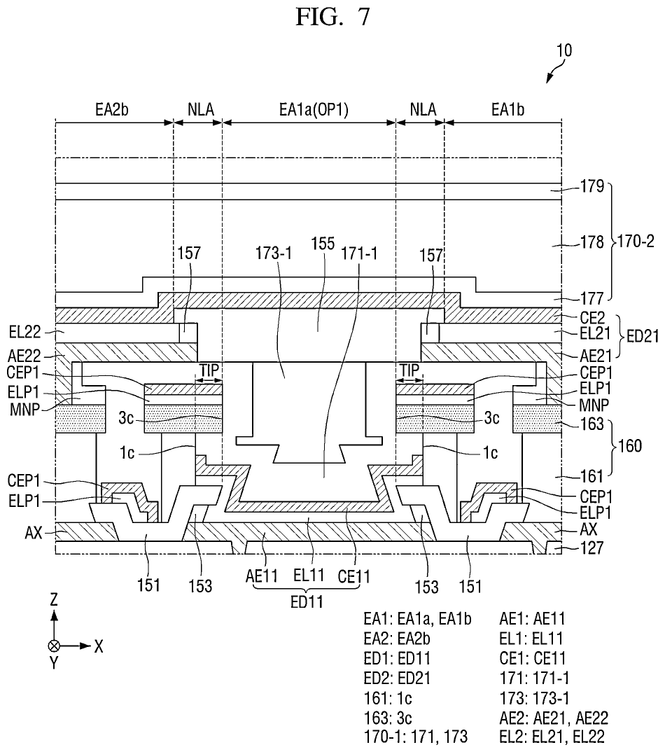

FIG. 7 is an enlarged cross-sectional view showing a first light emitting portion EA1a of a first light emitting area EA1 in FIG. 6.

Referring to FIG. 7, the first light emitting portion EA1a of the first light emitting area EA1 may be adjacent the non-light emitting area NLA. The second light emitting portion EA2b of the second light emitting area EA2 may be spaced apart in the first direction (negative X-axis direction) from the first light emitting portion EA1a with a portion of the non-light emitting area NLA being interposed therebetween. In addition, the second light emitting portion EA1b of the first light emitting area EA1 may be spaded apart in the first direction (positive X-axis direction) from the first light emitting portion EA1a of the first light emitting area EA1 with another portion of the non-light emitting area NLA interposed therebetween.

As described above, the first pixel defining layer 151 according to an embodiment may include the first opening OP1 defining the first light emitting portion EA1a of the first light emitting area EA1, and the first opening OP1 may expose a portion of the first anode electrode AE11.

The first pixel defining layer 151 may be positioned on the second via layer 127, and the first pixel defining layer 151 may cover edge portions of the first anode electrode AE11 and the auxiliary electrode AX. In other words, the first pixel defining layer 151 may contact the second via layer 127, the first anode electrode AE11, and the auxiliary electrode AX.

The first bank layer 161 according to an embodiment may be positioned on the first pixel defining layer 151 and the auxiliary electrode AX. The first bank layer 161 may include a metal with high electrical conductivity. As an example, the first bank layer 161 may include aluminum (Al).

In some embodiments, the first bank layer 161 disposed in a portion overlapping the non-light emitting area NLA may include a side surface 1c facing the first light emitting portion EA1a of the first light emitting area EA1. The side surface 1c of the first bank layer 161 may include a structure that is recessed toward the non-light emitting area NLA rather than being aligned with the opening OP1 in the first pixel defining layer 151. The side surface 1c of the first bank layer 161 may be in contact with the first light emitting layer EL11, the first cathode electrode CE11, and the first inorganic layer 171-1. As described above, the second electrode CE1 according to an embodiment may include portions that are spaced apart from each other and respectively overlap the first to third light emitting areas EA1, EA2, and EA3, and the portions of the second electrodes CE1 that are spaced apart from each other may be electrically connected through the first bank layer 161.

The second bank layer 163 may be positioned on the first bank layer 161. The second bank layer 163 may include a material with a lower etch rate than the first bank layer 161. As an example, the second bank layer 163 may include titanium Ti.

In some embodiments, the second bank layer 163 disposed in a portion overlapping the non-light emitting area NLA may include a side surface 3c facing the first light emitting portion EA1a of the first light emitting area EA1. The side surface 3c of the second bank layer 163 may have a shape that protrudes more toward the first light emitting portion EA1a than does the side surface 1c of the first bank layer 161. As a result, the second bank layer 163 may include a tip protruding toward the first light emitting portion EA1a. Therefore, an undercut may be formed between a lower portion of the tip of the second bank layer 163 and the side surface 1c of the first bank layer 161.

In some embodiments, a thickness of the second bank layer 163 in the third direction (Z-axis direction) may be less than a thickness of the first bank layer 161.

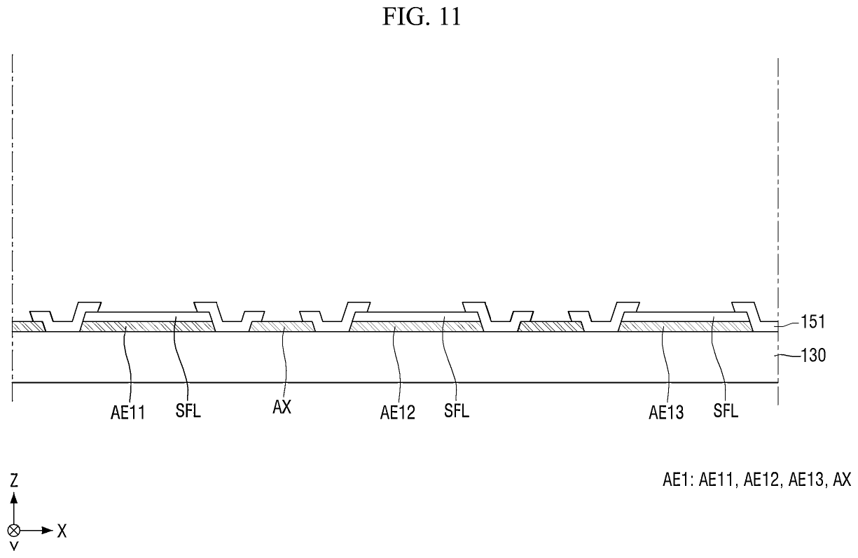

The display device 10 according to an embodiment may include a sacrificial layer (“SFL” in FIG. 11) during the fabricating process of the first display element ED1. The sacrificial layer SFL may be disposed between the first pixel defining layer 151 and the first electrode AE1, and then partially removed by a subsequent wet etching process. In this case, a portion of the sacrificial layer SFL that has not been removed may remain as a residual pattern 153 between the first pixel defining layer 151 and the first electrode AE1. The residual pattern 153 may be disposed to overlap in the third direction (Z-axis direction) the non-light emitting area NLA and the protruding tip TIP of the second bank layer 163, and the residual pattern 153 may be in contact with the first display light emitting layer EL1 in the first direction (X-axis direction).

In some embodiments, the residual pattern 153 may be completely surrounded by the first pixel defining layer 151, the first display light emitting layer EL1, and the first electrode AE1, and may be in contact with the first pixel defining layer 151, the first display light emitting layer EL1, and the first electrode AE1. As an example, the residual pattern 153 may include at least one of indium gallium zinc oxide (IGZO), zinc tin oxide (ZTO), and indium tin oxide (IZO).

The first light emitting layer EL11 included in the first display light emitting layer EL1 according to an embodiment may be disposed on the first anode electrode AE11 in a portion overlapping the first light emitting portion EA1a of the first light emitting area EA1, and the first light emitting layer EL11 according to an embodiment may be in contact with the side surface 1c of the first bank layer 161 in a portion overlapping the non-light emitting area NLA and may be completely covered by the first cathode electrode CE11. In addition, the first light emitting layer EL11 according to an embodiment may be in contact with the residual pattern 153 in a portion overlapping the non-light emitting area NLA.

The first cathode electrode CE11 included in the second electrode CE1 according to an embodiment may be disposed on the first light emitting layer EL11 in a portion overlapping the first light emitting portion EA1a of the first light emitting area EA1, and the first cathode electrode CE11 according to an embodiment may be in contact with the side surface 1c of the first bank layer 161 in a portion overlapping the non-light emitting area NLA, and the first cathode electrode may be completely covered by the first inorganic layer 171-1.

The first organic pattern ELP1 according to an embodiment may be disposed on the second bank layer 163 in a portion overlapping a periphery of the first light emitting portion EA1a of the first light emitting area EA1. In addition, the first organic pattern ELP1 may be disposed on the first pixel defining layer 151 in a portion overlapping the second light emitting portion EA1b of the first light emitting area EA1 and the second light emitting portion EA2b of the second light emitting area EA2. As the second bank layer 163 includes the tip during the fabricating process of the first light emitting layer EL11, the first organic pattern ELP1 may be a trace that is disconnected from the first light emitting layer EL11. That is, the first light emitting layer EL11 and the first organic pattern ELP11 may be spaced apart from each other.

The first electrode pattern CEP1 may be disposed on the first organic pattern ELP1 in a portion overlapping a periphery of the first light emitting portion EA1a of the first light emitting area EA1. In addition, the first electrode pattern CEP1 may be disposed on the first pixel defining layer 151 in a portion overlapping the second light emitting portion EA1b of the first light emitting area EA1 and the second light emitting portion EA2b of the second light emitting area EA2. As the second bank layer 163 includes the tip during the fabricating process of the second electrode CE1, the first electrode pattern CEP1 may be a trace that is disconnected from the first cathode electrode CE11.

The first organic pattern ELP1 and the first electrode pattern CEP1 may not be on the bank structure 160 disposed in contact with the auxiliary electrode AX according to an embodiment. The bank structure 160 disposed in contact with the auxiliary electrode AX is described below.

The first inorganic layer 171-1 included in the first encapsulation layer 171 according to an embodiment may completely cover the first cathode electrode CE11 in the portion overlapping the first light emitting portion EA1a of the first light emitting area EA1, and the first inorganic layer 171-1 may cover the side surface 1c of the first bank layer 161 and the protruding tip TIP of the second bank layer 163 in the portion overlapping the non-light emitting area NLA. The first inorganic layer 171-1 may be in contact with the side surface 1c of the first bank layer 161 and the protruding tip TIP of the second bank layer 163. In addition, the first inorganic layer 171-1 according to an embodiment may completely cover the first electrode pattern CEP1, the first pixel defining layer 151, the first bank layer 161, the second bank layer 163, and the monomer pattern MNP in the portions overlapping the second light emitting portion EA1b of the first light emitting area EA1 and the second light emitting portion EA2b of the second light emitting area EA2.

The first organic layer 173-1 included in the second encapsulation layer 173 according to an embodiment may be disposed on the first inorganic layer 171-1 in the portion overlapping the first light emitting portion EA1a of the first light emitting area EA1. The first organic layer 173-1 may not overlap the second light emitting portion EA1b of the first light emitting area EA1 and the second light emitting portion EA2b of the second light emitting area EA2. The second pixel defining layer 155 may be positioned on the first organic layer 173-1. As a result, the first organic layer 173-1 may be completely surrounded by the first inorganic layer 171-1 and the second pixel defining layer 155.

The second display element ED2 according to an embodiment may be positioned on the first thin film encapsulation layer 170-1. As described above, the second display element ED2 may overlap the second light emitting portion EA1b of the first light emitting area EA1 and the second light emitting portion EA2b of the second light emitting area EA2, and the second display element ED2 may not overlap the first light emitting portion EA1a of the first light emitting area EA1. The third electrode AE2 and the second display light emitting layer EL2 included in the second display element ED2 is described below.

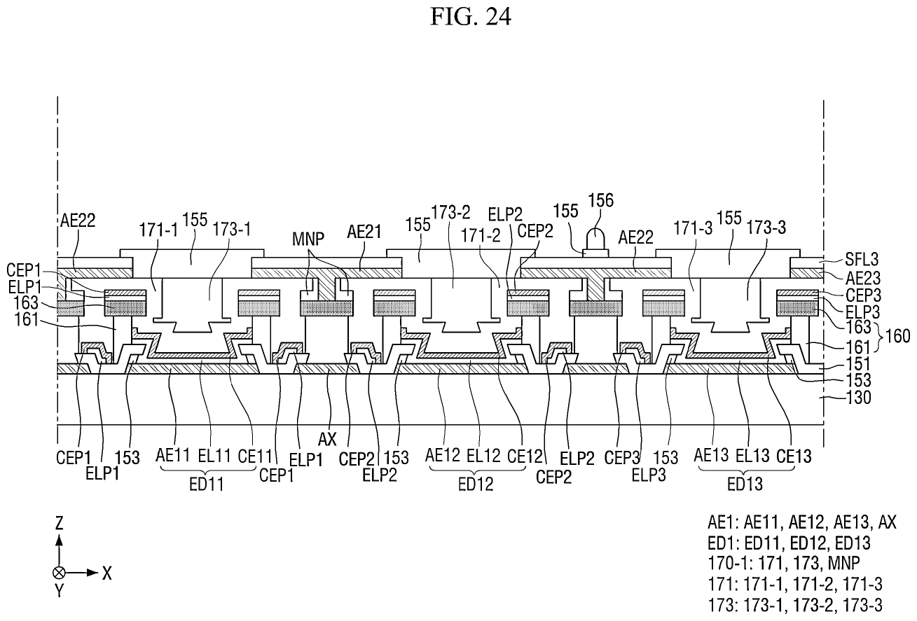

The display device 10 according to an embodiment may include a sacrificial layer (“SFL2” in FIG. 24) during the fabricating process of the second display element ED2. The sacrificial layer SFL2 may be disposed between the second pixel defining layer 155 and the third electrode AE2, and then partially removed by a subsequent wet etching process. In this case, a portion of the sacrificial layer SFL2 that has not been removed may remain as a residual pattern 157 between the second pixel defining layer 155 and the third electrode AE2. The residual pattern 157 may overlap the non-light emitting area NLA in the third direction (Z-axis direction) and may be disposed in contact with the second display light emitting layer EL2 in the first direction (X-axis direction).

In some embodiments, the residual pattern 157 may be completely surrounded by the second pixel defining layer 155, the second display light emitting layer EL2, and the third electrode AE2, and may be in contact with the second pixel defining layer 155, the second display light emitting layer EL2, and the third electrode AE2. As an example, the residual pattern 157 may include at least one of indium gallium zinc oxide (IGZO), zinc tin oxide (ZTO), and indium tin oxide (IZO).

The second pixel defining layer 155 may be disposed on the first thin film encapsulation layer 170-1 in a portion overlapping the first light emitting portion EA1a of the first light emitting area EA1. The second pixel defining layer 155 may define the second light emitting portion EA1b of the first light emitting area EA1 and the second light emitting portion EA2b of the second light emitting area EA2. Therefore, the second pixel defining layer 155 may space the first anode electrode AE21 and the second anode electrode AE22 from each other in the first direction (X-axis direction) and may space the first light emitting layer EL21 and the second light emitting layer EL22 from each other in the first direction (X-axis direction). In addition, the second pixel defining layer 155 according to an embodiment may overlap the first display element ED1 in the third direction (Z-axis direction).

As described above, the common electrode CE2 according to an embodiment may entirely cover the second display light emitting layer EL2 and the second pixel defining layer 155, and the second thin film encapsulation layer 170-2 may entirely cover the common electrode CE2.

For convenience of explanation, the first light emitting portion EA1a of the first light emitting area EA1 and the peripheral portions thereof are illustrated and described in detail, but the first light emitting portion EA2a of the second light emitting area EA2 and the peripheral portions thereof and the first light emitting portion EA3a of the third light emitting area EA3 and the peripheral portions thereof may include structures and features that are similar to those of the first light emitting portion EA1a of the first light emitting area EA1 and the peripheral portions thereof.

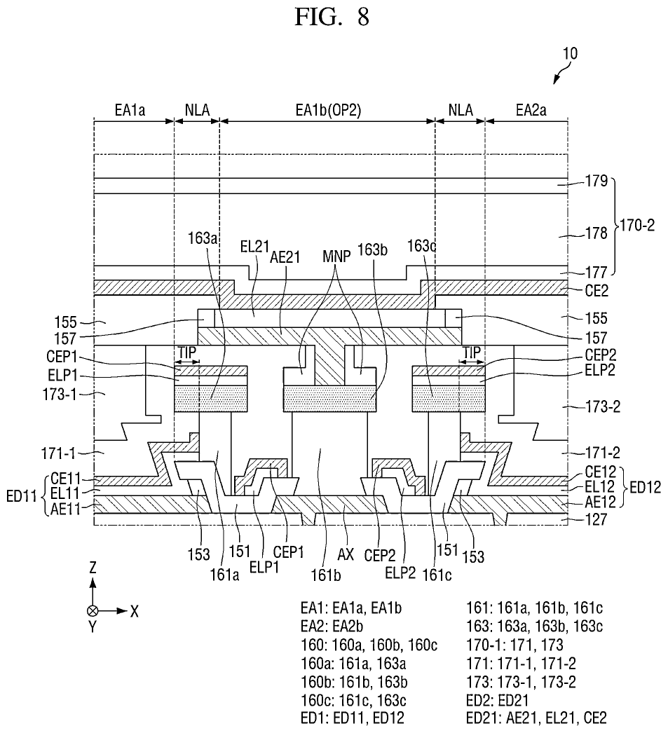

FIG. 8 is an enlarged cross-sectional view of a second light emitting portion EA1b of a first light emitting area EA1 in FIG. 6.

Referring to FIG. 8, the second light emitting portion EA1b of the first light emitting area EA1 may be adjacent in the first direction (X-axis direction) to a plurality of portions of non-light emitting area NLA and may be spaced apart from the second light emitting portion EA1b of the first light emitting area EA1 in the first direction (negative X-axis direction) with the non-light emitting area NLA interposed therebetween. In addition, the second light emitting portion EA1b of the first light emitting area EA1 may be spaced apart from the first light emitting portion EA2a of the second light emitting area EA2 in the first direction (positive X-axis direction) with the non-light emitting area NLA interposed therebetween.

The first anode electrode AE11, the auxiliary electrode AX, and the second anode electrode AE12 according to an embodiment may be spaced apart in the first direction (X-axis direction), and portions of the first pixel defining layer 151 may be in the spaces between he first anode electrode AE11, the auxiliary electrode AX, and the second anode electrode AE12. Specifically, the first anode electrode AE11 may be disposed in a portion overlapping the first light emitting portion EA1a of the first light emitting area EA1, the auxiliary electrode AX may be disposed in a portion overlapping the second light emitting portion EA1b of first light emitting area EA1, and the second anode electrode AE12 may be disposed in a portion overlapping the first light emitting portion EA2a of the second light emitting area EA2.

The bank structure 160 according to an embodiment may include a first portion 160a, a second portion 160b, and a third portion 160c. The first portion 160a, the second portion 160b, and the third portion 160c of the bank structure 160 may be spaced apart in the first direction (X-axis direction) with the first encapsulation layer 171 interposed therebetween. During the fabricating process of the display device 10, the first portion 160a, the second portion 160b, and the third portion 160c of the bank structure 160 may be integrally formed and then divided, e.g., by a photo pattern process, into the form illustrated in the drawings. Therefore, the first portion 160a, the second portion 160b, and the third portion 160c of the bank structure 160 may include the same material or materials. The fabricating process of the bank structure 160 is described in more detail below.

In some embodiments, the first portion 160a of the bank structure 160 may include a first portion 161a of the first bank layer 161 and a first portion 163a of the second bank layer 163.

The first portion 161a of the first bank layer 161 may be disposed on the first pixel defining layer 151. The first portion 161a may be positioned in contact with the first pixel defining layer 151 and the first display element ED1. Specifically, the first portion 161a may be in contact with the first light emitting layer EL11 and the first cathode electrode CE11 included in the first light emitting element ED11 in a portion overlapping the non-light emitting area NLA and may be in contact with the first inorganic layer 171-1 in a portion overlapping the second light emitting portion EA1b of the first light emitting area EA1.

Therefore, the first portion 161a of the first bank layer 161 may be in contact with the first light emitting layer EL11, the first cathode electrode CE11, the first inorganic layer 171-1, and the first pixel defining layer 151 and may be surrounded by the first light emitting layer EL11, the first cathode electrode CE11, the first inorganic layer 171-1, the second bank layer 163, and the first pixel defining layer 151.

The first portion 163a of the second bank layer 163 may be disposed on the first portion 161a of the first bank layer 161. The first portion 163a of the second bank layer 163 may overlap the non-light emitting area NLA and may have a tip TIP that protrudes toward the first light emitting portion EA1a of the first light emitting area EA1 more than does the first portion 161a of the first bank layer 161. The first organic pattern ELP1 and the first electrode pattern CEP1 may be positioned on the first portion 163a of the second bank layer 163, and the first portion 163a of the second bank layer 163 may be surrounded by the first inorganic layer 171-1.

In some embodiments, the second portion 160b of the bank structure 160 may include a second portion 161b of the first bank layer 161 and a second portion 163b of the second bank layer 163.

The second portion 161b of the first bank layer 161 may be disposed on the first pixel defining layer 151 and the auxiliary electrode AX. The second portion 161b may be in contact with the auxiliary electrode AX. As a result, the second portion 161b may be electrically connected to the auxiliary electrode AX.

The second portion 161b of the first bank layer 161 may be spaced apart from the first portion 161a in the first direction (X-axis direction) with a portion of the first inorganic layer 171-1 interposed therebetween. The second portion 161b may be in contact with the first inorganic layer 171-1 in the first direction (negative X-axis direction) and may be in contact with the second inorganic layer 171-2 in the first direction (positive X-axis direction). In other words, the first inorganic layer 171-1 and the second inorganic layer 171-2 may be spaced apart from each other by the second portion 161b of the first bank layer 161.

The second portion 163b of the second bank layer 163 may be disposed on the second portion 161b of the first bank layer 161. The second portion 163b may be in contact with the first anode electrode AE21 in the third direction (positive Z-axis direction) and may also be in contact with the second portion 161b of the first bank layer 161 in the third direction (negative Z-axis direction). Therefore, the auxiliary electrode AX and the first anode electrode AE21 may be electrically connected to each other by the second portion 160b of the bank structure 160.

The monomer pattern MNP may be positioned on the second portion 163b of the second bank layer 163. The monomer pattern MNP may be disposed on sides of the first anode electrode AE21 in the first direction (X-axis direction). The monomer pattern MNP may cover the second portion 163b of the second bank layer 163 during the fabricating process of the second encapsulation layer 173, and then a photo patter process may form the monomer pattern MNP as illustrated. Formation of the monomer pattern MNP is described in more detail below.

The second portion 163b of the second bank layer 163 may be in contact with the second inorganic layer 171-2 in the first direction (positive X-axis direction) and may also be in contact with the first inorganic layer 171-1 in the first direction (negative X-axis direction). In other words, the first inorganic layer 171-1 and the second inorganic layer 171-2 may be spaced apart from each other by the second portion 163b of the second bank layer 163.

The first to third organic patterns ELP1, ELP2, and ELP3 and the first to third electrode patterns CEP1, CEP2, and CEP3 may not be disposed on the second portion 160b of the bank structure 160 according to an embodiment. This may result from an etching process in the fabricating process of the display device 10. The details thereof are described below.

In some embodiments, the third portion 160c of the bank structure 160 may include a third portion 161c of the first bank layer 161 and a third portion 163c of the second bank layer 163.

The third portion 161c of the first bank layer 161 may be disposed on the first pixel defining layer 151. The third portion 161c may be in contact with the first pixel defining layer 151 and the second light emitting element ED12. Specifically, the third portion 161c may contact the second light emitting layer EL12 and the second cathode electrode CE12 in a portion overlapping the non-light emitting area NLA and may contact the second inorganic layer 171-2 in a portion overlapping the second light emitting portion EA1b of the first light emitting area EA1. Therefore, the third portion 161c of the first bank layer 161 may be in contact with the second light emitting layer EL12, the second cathode electrode CE12, the second inorganic layer 171-2, the first pixel defining layer 151, and the second bank layer 163 and may be surrounded by the second light emitting layer EL12, the second cathode electrode CE12, the second inorganic layer 171-2, the first pixel defining layer 151, and the second bank layer 163.

The third portion 163c of the second bank layer 163 may be disposed on the third portion 161c of the first bank layer 161. The third portion 163c of the second bank layer 163 may have a tip TIP that protrudes toward the first light emitting portion EA2a of the second light emitting area EA2 more than does the third portion 161c of the first bank layer 161. The second organic pattern ELP2 and the second electrode pattern CEP2 may be positioned on the third portion 163c of the second bank layer 163, and the third portion 163c of the second bank layer 163 may be surrounded by the second inorganic layer 171-2.

The first organic pattern ELP1 and the first electrode pattern CEP1 may be positioned on an area of the first pixel defining layer 151 between the first portion 160a and the second portion 160b of the bank structure 160. This portion of the first organic pattern ELP1 may be in contact with the first pixel defining layer 151, and the first electrode pattern CEP1 may cover the portion the first organic pattern ELP1 between the first portion 160a and the second portion 160b of the bank structure 160.

In addition, the second organic pattern ELP2 and the second electrode pattern CEP2 may be positioned on an area of the first pixel defining layer 151 between the third portion 160c and the second portion 160b of the bank structure 160. This portion of the second organic pattern ELP2 may be in contact with the first pixel defining layer 151, and the second electrode pattern CEP2 may cover the portion of the second organic pattern ELP2 between the third portion 160c and the second portion 160b of the bank structure 160.

The first light emitting element ED21 included in the second display element ED2 according to an embodiment may be positioned on the monomer pattern MNP, the first inorganic layer 171-1, and the second inorganic layer 171-2. In addition, the first light emitting element ED21 included in the second display element ED2 may overlap the first portion 160a, the second portion 160b, and the third portion 160c of the bank structure 160 in the third direction (Z-axis direction).

For convenience of explanation, the second light emitting portion EA1b of the first light emitting area EA1 and the peripheral portions thereof are illustrated and described in detail, but the second light emitting portion EA2b of the second light emitting area EA2 and the peripheral portions thereof and the second light emitting portion EA3b of the third light emitting area EA3 and the peripheral portions thereof may include structures and features similar to those of the second light emitting portion EA1b of the first light emitting area EA1 and the peripheral portions thereof.

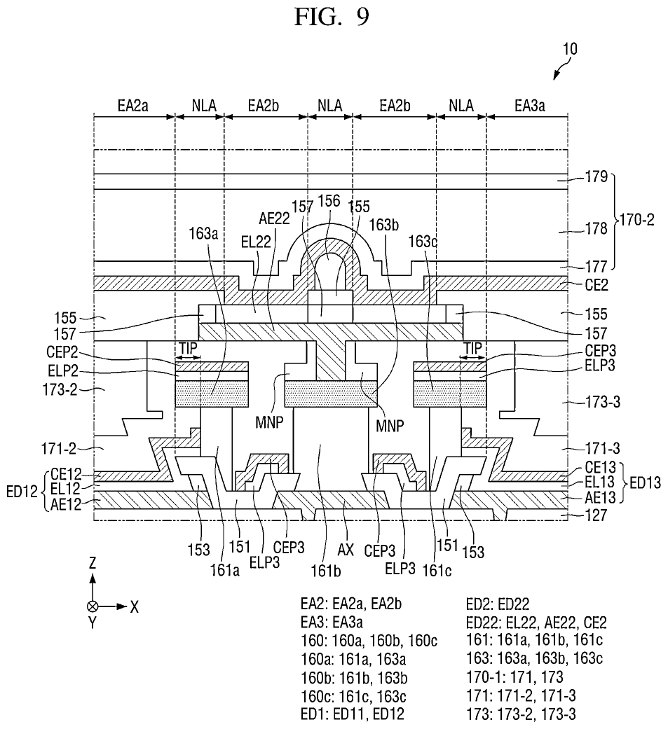

FIG. 9 is an enlarged cross-sectional view showing the second light emitting portion EA2b of the second light emitting area EA2 overlapping the peripheral portion of the spacer 156 in FIG. 6.

Referring to FIG. 9, the spacer 156 may be disposed in a portion overlapping the non-light emitting area NLA. The non-light emitting area NLA in which the spacer 156 overlaps may be surrounded by or adjacent in the first direction (X-axis direction) to the second light emitting portions EA2b of the second light emitting area EA2.

The second anode electrode AE12, the auxiliary electrode AX, and the third anode electrode AE13 according to an embodiment may be disposed on the second via layer 127 and may be spaced apart from each other in the first direction (X-axis direction) with regions of the first pixel defining layer 151 being between the second anode electrode AE12, the auxiliary electrode AX, and the third anode electrode AE13. Specifically, the second anode electrode AE12 may be disposed in a portion overlapping the first light emitting portion EA2a of the second light emitting area EA2, the auxiliary electrode AX may be disposed in a portion overlapping the second light emitting portion EA2b of second light emitting area EA2, and the third anode electrode AE13 may be disposed in a portion overlapping the first light emitting portion EA3a of the third light emitting area EA3. The second anode electrode AE12 and the third anode electrode AE13 according to an embodiment may not overlap the spacer 156 in the third direction (Z-axis direction), and the auxiliary electrode AX according to an embodiment may overlap the spacer 156 in the third direction (Z-axis direction).

The bank structure 160 according to an embodiment may include a first portion 160a, a second portion 160b, and a third portion 160c. The first portion 160a, the second portion 160b, and the third portion 160c of the bank structure 160 may be spaced apart in the first direction (X-axis direction) with the first encapsulation layer 171 interposed therebetween.

In some embodiments, the first portion 160a of the bank structure 160 may include the first portion 161a of the first bank layer 161 and the first portion 163a of the second bank layer 163, the second portion 160b thereof may include the second portion 161b of the first bank layer 161 and the second portion 163b of the second bank layer 163, and the third portion 160c thereof may include the third portion 161c of the first bank layer 161 and the third portion 163c of the second bank layer 163. In addition, the first portion 160a of the bank structure 160 may be in contact with the second light emitting element ED12 included in the first display element ED1, and the third portion 160c of the bank structure 160 may be in contact with the third light emitting element ED13 included in the first display element ED1. Specifically, the first portion 160a may be in contact with the second light emitting layer EL12 and the second cathode electrode CE12, and the third portion 160c may be in contact with the third light emitting layer EL13 and the third cathode electrode CE13. The second portion 163b of the bank structure 160 may be in contact with the second anode electrode AE22 and may overlap the spacer 156 in the third direction (Z-axis direction).

The second light emitting element ED22 included in the second display element ED2 according to an embodiment may be positioned on the monomer pattern MNP, the second inorganic layer 171-2, and the third inorganic layer 171-3. In addition, the second light emitting element ED22 included in the second display element ED2 may overlap the first portion 160a, the second portion 160b, and the third portion 160c of the bank structure 160 in the third direction (Z-axis direction).

The residual pattern 157 may be disposed on the second anode electrode AE22 according to an embodiment. Portions of the residual pattern 157 may be spaced apart and overlap the non-light emitting area NLA on the second anode electrode AE22. A portion of the residual pattern 157 according to an embodiment may overlap the spacer 156 in the third direction (Z-axis direction).

As described above, the display device 10 according to an embodiment may include the sacrificial layer (“SFL2” in FIG. 24) during the fabricating process of the second display element ED2. The sacrificial layer SFL2 may be disposed between the second pixel defining layer 155 and the third electrode AE2, and then partially removed by a subsequent wet etching process. In this case, a portion of the sacrificial layer SFL2 that has not been removed may remain as the residual pattern 157 between the second pixel defining layer 155 and the third electrode AE2. The residual pattern 157 may overlap the non-light emitting area NLA in the third direction (Z-axis direction) and may be disposed in contact with the second display light emitting layer EL2 in the first direction (X-axis direction).

The second light emitting layer EL22 according to an embodiment may be positioned between portions of the residual pattern 157 spaced apart from each other. The second light emitting layer EL22 according to an embodiment may be disposed in contact with a portion of the residual pattern 157 overlapping the spacer 156.

The second pixel defining layer 155 may be disposed on the residual pattern 157 overlapping the spacer 156 according to an embodiment. In other words, the second pixel defining layer 155 according to an embodiment may be disposed between the spacer 156 and the residual pattern 157. As described above, openings in the second pixel defining layer 155 disposed to be adjacent to each other in the first direction (X-axis direction) may define the second light emitting portion EA2b of the second light emitting area EA2.

The common electrode CE2 according to an embodiment may completely cover the second light emitting layer EL22, the second pixel defining layer 155, and the spacer 156 and may be entirely thereon. The common electrode CE2 according to an embodiment may be in contact with the second light emitting layer EL22, the second pixel defining layer 155, and the spacer 156. In addition, the second thin film encapsulation layer 170-2 may be formed to entirely cover the common electrode CE2.

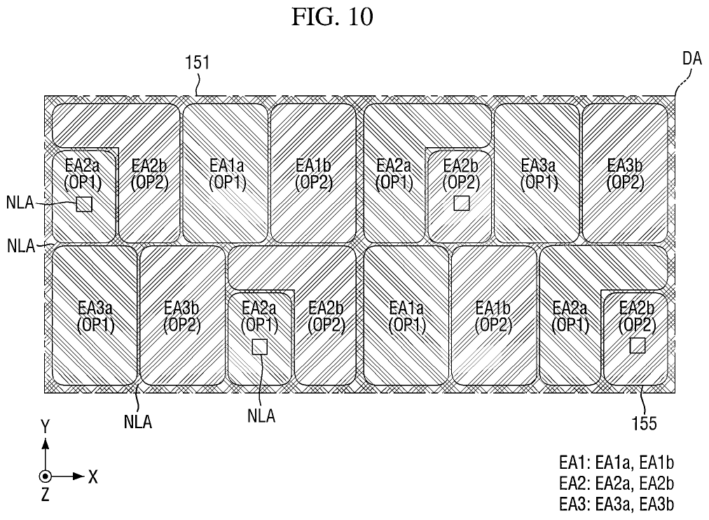

FIG. 10 is a plan view illustrating an arrangement of the first pixel defining layer 151 and the second pixel defining layer 155 in FIG. 5.

Referring to FIG. 10, in plan view, the first opening OP1 may be defined by the first pixel defining layer 151, and in plan view, the first light emitting portion EA1a of the first light emitting area EA1, the first light emitting portion EA2a of the second light emitting area EA2, and the first light emitting portion EA3a of the third light emitting area EA3 may be defined by the first opening OP1. That is, in plan view, the first pixel defining layer 151 may be disposed to completely surround the first light emitting portion EA1a of the first light emitting area EA1, the first light emitting portion EA2a of the second light emitting area EA2, and the first light emitting portion EA3a of the third light emitting area EA3. In other words, in plan view, the first pixel defining layer 151 may expose the first light emitting portion EA1a of the first light emitting area EA1, the first light emitting portion EA2a of the second light emitting area EA2, and the first light emitting portion EA3a of the third light emitting area EA3, and the first pixel defining layer 151 may have a mesh shape.

In addition, in plan view, the second opening OP2 may be defined by the second pixel defining layer 155, and in plan view, the second light emitting portion EA1b of the first light emitting area EA1, the second light emitting portion EA2b of the second light emitting area EA2, and the second light emitting portion EA3b of the third light emitting area EA3 may be defined by the second opening OP2. That is, in plan view, the second pixel defining layer 155 may be disposed to completely surround the second light emitting portion EA1b of the first light emitting area EA1, the second light emitting portion EA2b of the second light emitting area EA2, and the second light emitting portion EA3b of the third light emitting area EA3. In other words, in plan view, the second pixel defining layer 155 may expose the second light emitting portion EA1b of the first light emitting area EA1, the second light emitting portion EA2b of the second light emitting area EA2, and the second light emitting portion EA3b of the third light emitting area EA3, and the second pixel defining layer 155 may have a mesh shape.

As illustrated in FIG. 10, in plan view, a portion of the first pixel defining layer 151 and a portion of the second pixel defining layer 155 may overlap in the third direction (Z-axis direction). In plan view, the portion where the first pixel defining layer 151 and the second pixel defining layer 155 overlap in the third direction (Z-axis direction) may be defined as a non-light emitting area NLA.

In addition, in plan view, the non-light emitting area NLA may include a portion disposed inside the second light emitting area EA2 according to an embodiment. The non-light emitting area NLA disposed inside the second light emitting area EA2 may be completely surrounded by the second light emitting area EA2. As described above, the spacer 156 and the second pixel defining layer 155 may be disposed to overlap in the non-light emitting area NLA disposed inside the second light emitting area EA2.

FIGS. 11 to 26 are cross-sectional views schematically illustrating structures formed by a method of fabricating the display element layer 150 of FIG. 6. Specifically, FIGS. 11 to 26 are cross-sectional views illustrating a process of fabricating the first light emitting structure 150-1 and the second light emitting structure 150-2 of the display element layer 150.

Referring to FIG. 11, a first electrode AE1 is formed on the thin film transistor layer 130 and a sacrificial layer SFL is formed on the first electrode AE1. The first electrode AE1 may include a first anode electrode AE11, a second anode electrode AE12, a third anode electrode AE13, and an auxiliary electrode AX. The first anode electrode AE11, the second anode electrode AE12, the third anode electrode AE13, and the auxiliary electrode AX may be spaced apart from each other on the thin film transistor layer 130. Although not shown in FIG. 11, the thin film transistor layer 130 may be disposed on the substrate 110, and a structure of the thin film transistor layer 130 may be the same as that described above with reference to FIG. 6. A detailed description thereof is not repeated here.

The sacrificial layer SFL may assist in preventing an upper surface of the first electrode AE1 and the first pixel defining layer 151 from coming into contact with each other. The sacrificial layer SFL may include an oxide semiconductor. As an example, the sacrificial layer SFL may include at least one of indium gallium zinc oxide (IGZO), zinc tin oxide (ZTO), and indium tin oxide (ITO).

Next, a first pixel defining layer 151 is formed covering a portion of the first anode electrode AE11, the second anode electrode AE12, and the third anode electrode AE13 and a portion of the auxiliary electrode AX. The first pixel defining layer 151 may be in contact with edges of the auxiliary electrode AX and the first electrode AE1, respectively, and the first pixel defining layer 151 may expose portions of the first anode electrode AE11, the second anode electrode AE12, the third anode electrode AE13, and the auxiliary electrode AX.

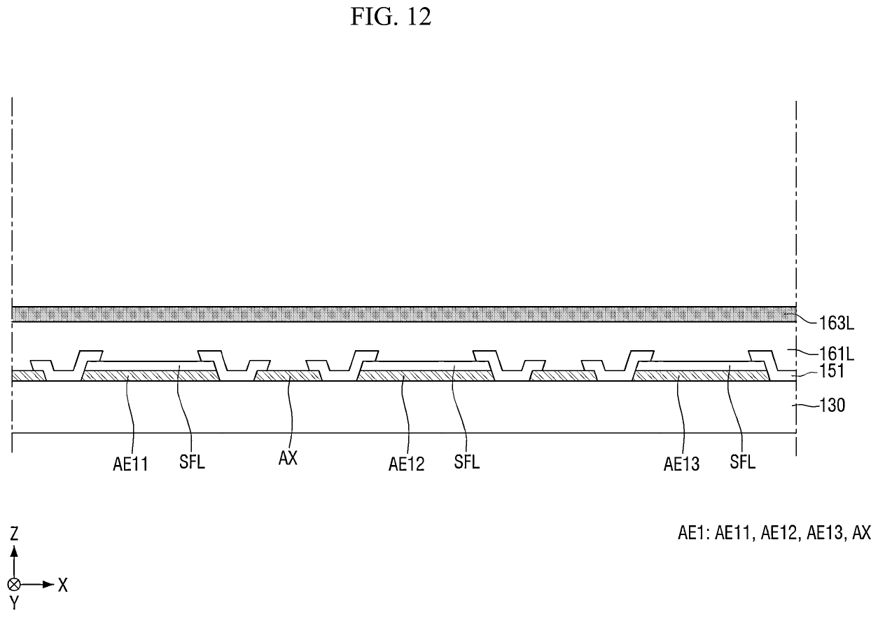

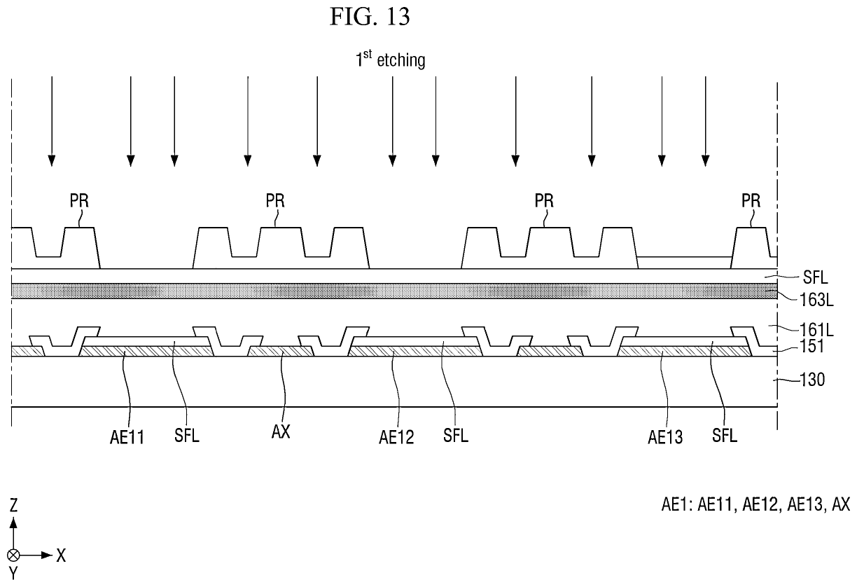

Next, referring to FIGS. 12 and 13, a first bank material layer 161L is formed to entirely cover the sacrificial layer SFL and the first pixel defining layer 151 disposed on the first electrode AE1, and a second bank material layer 163L is formed to entirely cover the first bank material layer 161L.

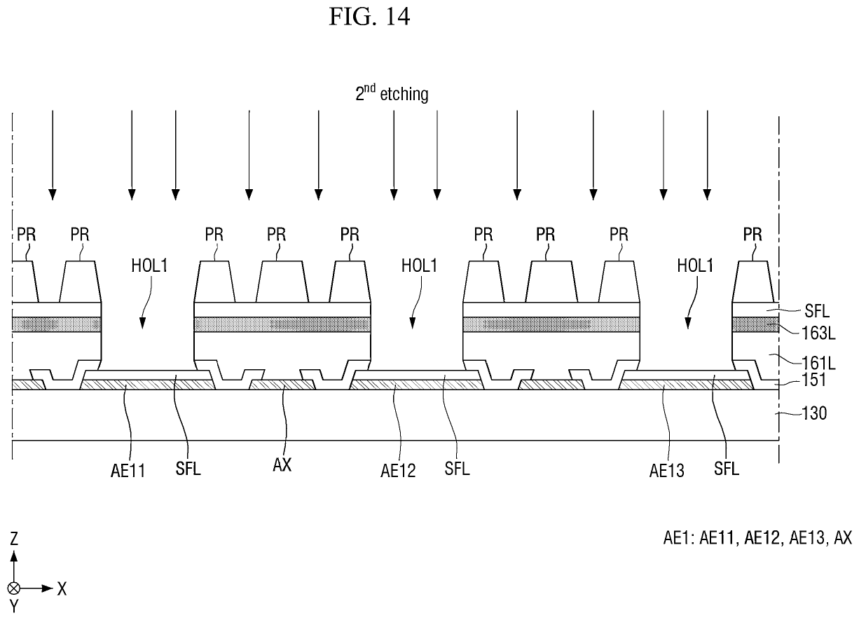

Next, a sacrificial layer SFL and a photoresist PR are formed on the second bank material layer 163L, and a first etching process is performed to etch a portion of the first bank material layer 161L and the second bank material layer 163L using the sacrificial layer SFL and the photoresist PR as a mask. The sacrificial layer SFL according to an embodiment may include an oxide semiconductor. Through such a process, a first hole HOL1 may be formed in a portion overlapping the first electrode AE1 as shown in FIG. 14.

Regions of the photoresist PR may be spaced apart from each other on the bank material layers 161L and 163L, and a thickness of the photoresist PR may be adjusted depending on the shape that etching may pattern in underlying layers. For example, a first etching process may be performed as dry etching.

Next, referring to FIGS. 14 to 16, a second etching process is performed using the photoresist PR as a mask. For example, in the second etching process, a wet etching process and a dry etching process may be alternately performed.

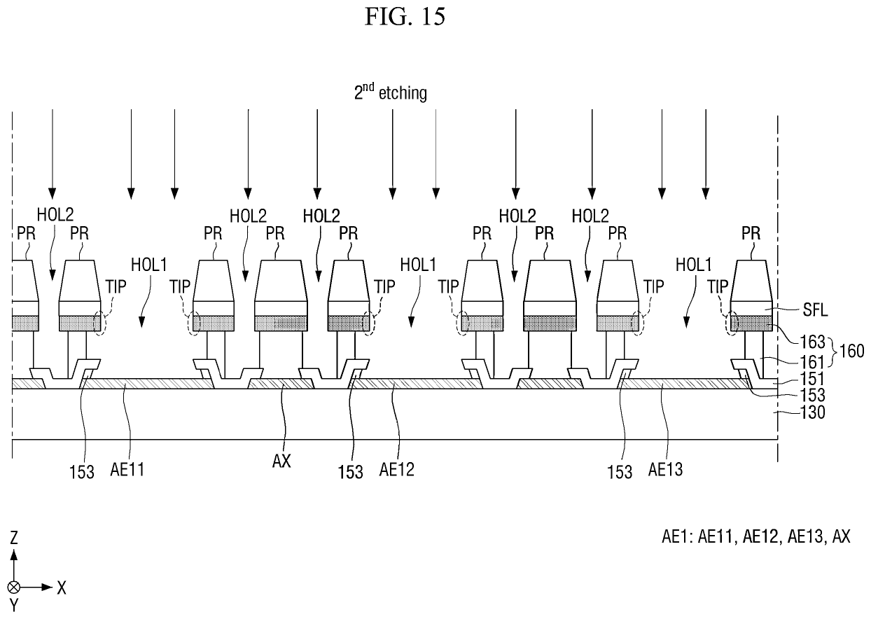

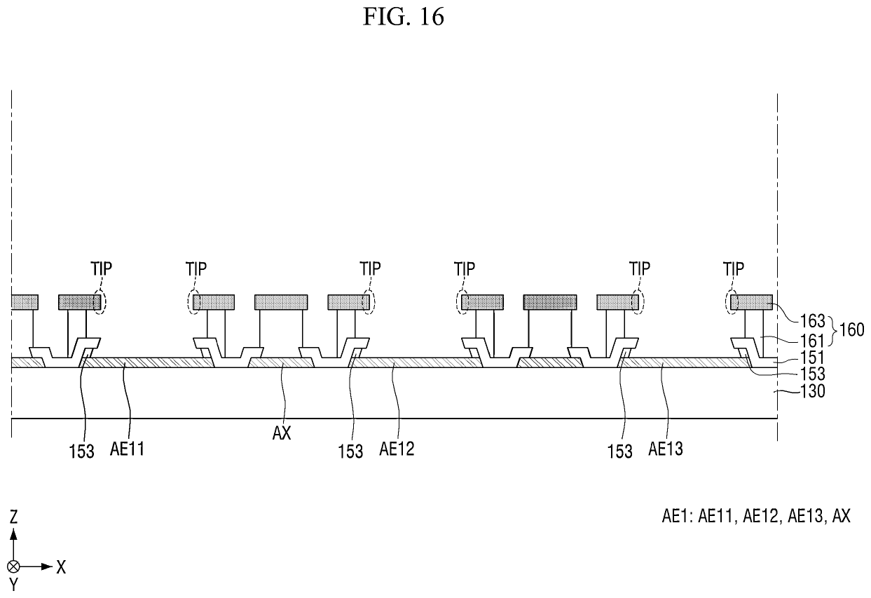

Through such a process, a portion of the sacrificial layer SFL disposed to overlap the first hole HOL1 may be removed. However, as illustrated in FIGS. 15 and 16, the sacrificial layer SFL is not completely removed and may partially remain as a residual pattern 153 in a space between the first pixel defining layer 151 and the first electrode AE1 in the third direction (Z-axis direction).

At the same time, a second hole HOL2 may be formed inside the bank structure 160 in a portion overlapping the first pixel defining layer 151. The second hole HOL2 may separate portions the bank structure 160, which may be spaced apart in a portion overlapping the first anode electrode AE11, a portion overlapping the second anode electrode AE12, and a portion overlapping the auxiliary electrode AX. In addition, a portion of the first pixel defining layer 151 may be exposed by the second hole HOL2.

In addition, through such a process, the inside of the first bank material layer 161L disposed to overlap the first hole HOL1 may be recessed in the first direction (X-axis direction) more than the second bank material layer 163L is recessed in the direction toward the auxiliary electrode AX. The first bank material layer 161L according to an embodiment may include a material that has a faster etch rate than the second bank material layer 163L. Therefore, by performing such an etching process, a side surface of the second bank material layer 163L may protrude further than a side surface of the first bank material layer 161L, and the bank structure 160 according to an embodiment may have the form of the first bank layer 161 and the second bank layer 163 illustrated in FIG. 16 after removal of the photoresist PR. In other words, through such a process, the second bank layer 163 may have a tip that protrudes more toward the first hole HOL1 more than the side surface of the first bank layer 161 does, and an undercut may be formed between the protruding tip of the second bank layer 163 and the first bank layer 161. After the second etching process, the photoresist PR and a portion of the sacrificial layer SFL may be removed.

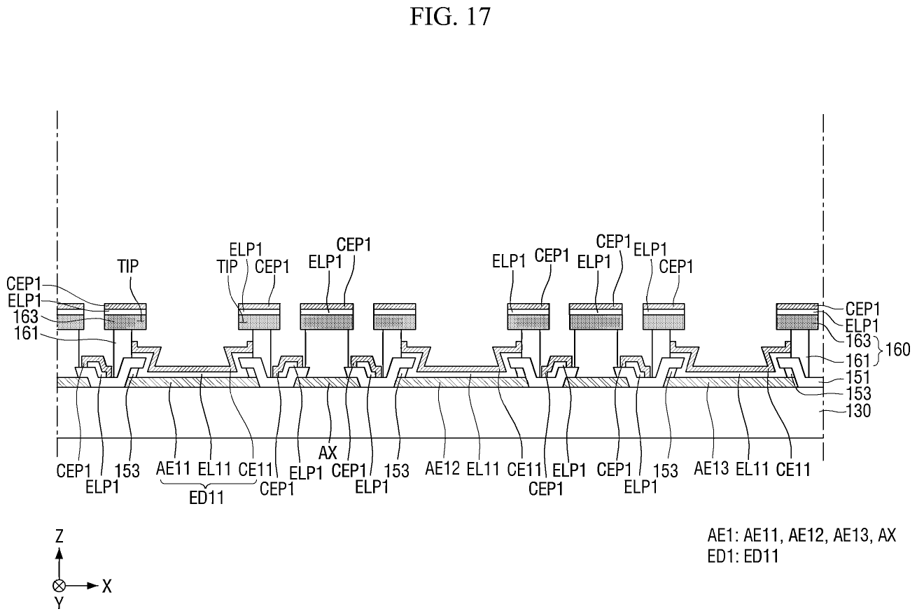

Next, referring to FIG. 17, a first light emitting layer EL11 and a first cathode electrode CE11 are deposited on each of the first anode electrode AE11, the second anode electrode AE12, and the third anode electrode AE13. The first light emitting layer EL11 and the first cathode electrode CE11 may be simultaneously deposited on the first anode electrode AE11, the second anode electrode AE12, and the third anode electrode AE13 without a mask.

In an embodiment, the first light emitting layer EL11 may be formed through a thermal evaporation process. The display device 10 included in an embodiment may form the first light emitting layer EL11 in overlapping portions on each of the first anode electrode AE11, the second anode electrode AE12, and the third anode electrode AE13 without a mask as the second bank layer 163 includes the protruding tip TIP. However, the deposition process of forming the first light emitting layer EL11 according to an embodiment may be performed at an angle of 45° to 50° from an upper surface of the first electrode AE1. Therefore, the first light emitting layer EL11 may be formed to fill a space spaced between the first electrode AE1 and the first pixel defining layer 151, and the first light emitting layer EL11 may be formed on a portion of the side surface of the first bank layer 161 covered by the protruding tip TIP of the second bank layer 163 and the side surface overlapping the protruding tip TIP of the second bank layer 163.

In such a process, a first organic pattern ELP1 may be formed on the second bank layer 163 according to an embodiment. The first organic pattern ELP1 may be formed by disconnecting the first light emitting layer EL11 by the tip TIP of the second bank layer 163. The first organic pattern ELP1 may also be disposed on the first pixel defining layer 151 to overlap the space between the bank structures 160.

The deposition process of forming the first cathode electrode CE11 according to an embodiment may be performed at an angle of 30° or less from the upper surface of the first electrode AE1. In other words, compared to the deposition process of forming the first light emitting layer EL11, the deposition process of forming the first cathode electrode CE11 may be performed to be inclined in a relatively more horizontal direction. As a result, the first cathode electrode CE11 may completely cover the first light emitting layer EL11 and may be formed on a portion of the side surface of the first bank layer 161 covered by the protruding tip TIP of the second bank layer 163 and the side surface overlapping the protruding tip TIP of the second bank layer 163.

In such a process, a first electrode pattern CEP1 may be positioned on the first organic pattern ELP1 according to an embodiment. The first electrode pattern CEP1 may be formed by disconnecting the first cathode electrode CE11 by the tip TIP of the second bank layer 163. The first electrode pattern CEP1 may be disposed to cover the first organic pattern ELP1 on the first pixel defining layer 151 while overlapping the space between the bank structures 160.

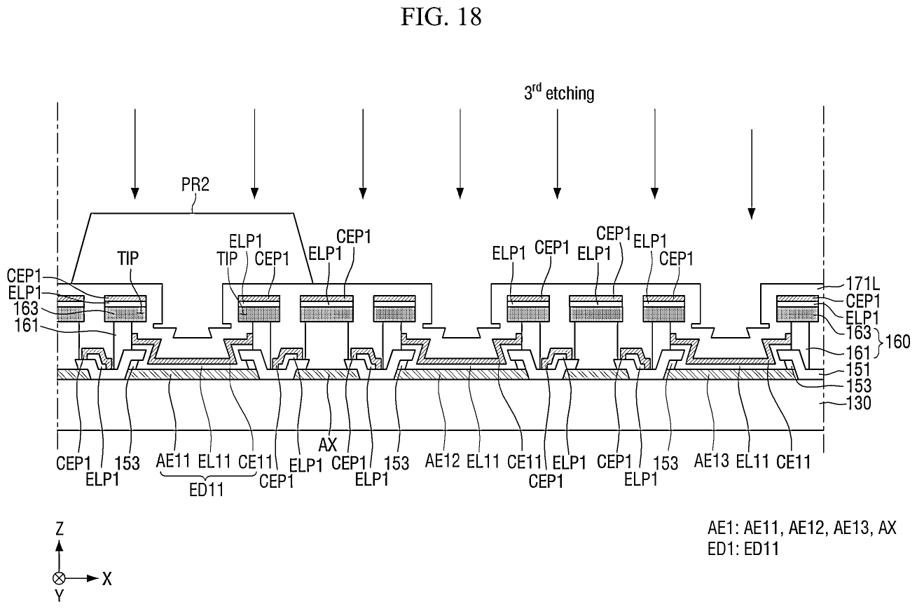

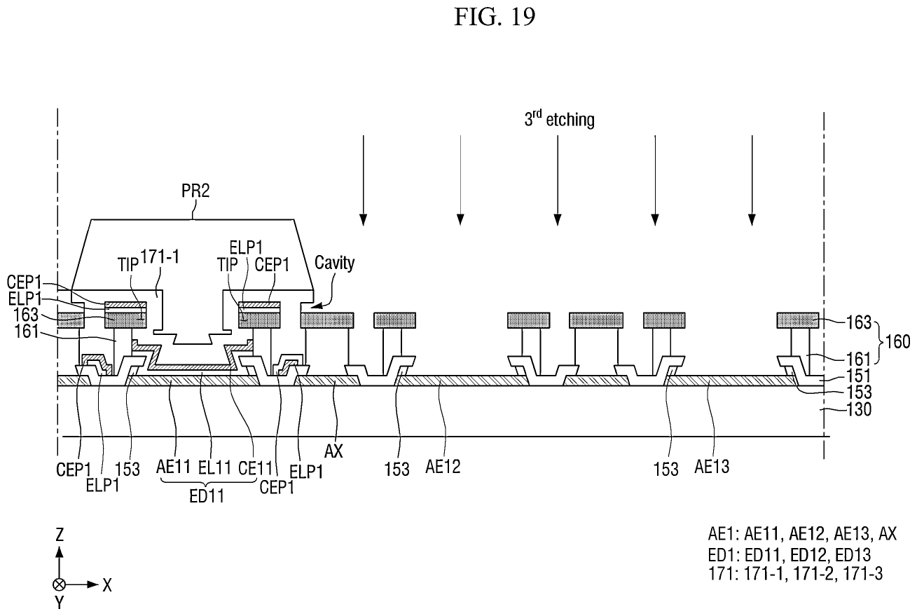

Referring to FIGS. 18 and 19, a first encapsulation material layer 171L is formed to completely cover the first cathode electrode CE11 and the first electrode pattern CEP1. Next, after photoresist PR2 is formed on a portion overlapping the first anode electrode AE11 and a periphery of the first anode electrode AE11, a third etching process is performed.

Through such a process, as illustrated in FIG. 19, the first light emitting layer EL11, the first cathode electrode CE11, the first organic pattern ELP1, the first electrode pattern CEP1, and the first encapsulation material layer 171L disposed in a portion excluding the first anode electrode AE11 and the periphery of the first anode electrode AE11 may be removed. As a result, the first light emitting element ED11 according to an embodiment may be formed, and the first encapsulation material layer 171L may be patterned to form the first inorganic layer 171-1. The first cathode electrode CE11 and the first electrode pattern CEP1 may be completely covered by the first inorganic layer 171-1, and a cavity may be formed between a portion of the second bank layer 163 and the first inorganic layer 171-1.

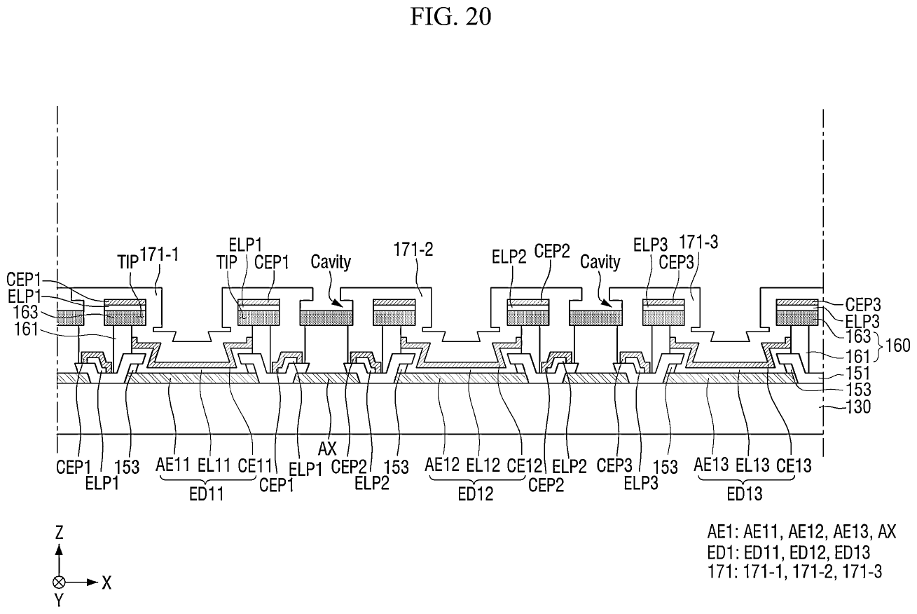

Referring to FIG. 20, thereafter, a second light emitting layer EL12 and a second cathode electrode CE12 are formed on the first anode electrode AE11, the second anode electrode AE12, and the third anode electrode AE13 through repetition of the same process described above for forming the first light emitting layer EL11 and the first cathode electrode CE12. Similarly, a second organic pattern ELP2 and a second electrode pattern CEP2 are formed on the second bank layer 163 and the first pixel defining layer 151 to overlap a peripheral portion of the first anode electrode AE11, a peripheral portion of the second anode electrode AE12, and a peripheral portion of the third anode electrode AE13.

Next, after a second inorganic layer 171-2 is formed to overlap the first anode electrode AE11, the second anode electrode AE12, and the third anode electrode AE13, the second light emitting layer EL12, the second cathode electrode CE12, the second organic pattern ELP2, and the second electrode pattern CEP2 excluding the second anode electrode AE12 and the peripheral portion of the second anode electrode AE12 are removed.

As a result, a second light emitting element ED12 may be formed, the second inorganic layer 171-2 may be spaced apart from the first inorganic layer 171-1, and the second cathode electrode CE12 and the second electrode pattern CEP2 may be completely covered by the second inorganic layer 171-2. In addition, a cavity may be formed between a portion of the second bank layer 163 and the second inorganic layer 171-2.

Thereafter, a third light emitting layer EL13 and a third cathode electrode CE13 are formed on the first anode electrode AE11, the second anode electrode AE12, and the third anode electrode AE13 through further repetition the same process, and a third organic pattern ELP3 and a third electrode pattern CEP3 are formed on the second bank layer 163 and the first pixel defining layer 151 to overlap a peripheral portion of the first anode electrode AE11, a peripheral portion of the second anode electrode AE12, and a peripheral portion of the third anode electrode AE13.

Next, after a third inorganic layer 171-3 is formed to overlap the first anode electrode AE11, the second anode electrode AE12, and the third anode electrode AE13, the third light emitting layer EL13, the third cathode electrode CE13, the third organic pattern ELP3, and the third electrode pattern CEP3 excluding the third anode electrode AE13 and the peripheral portion of the third anode electrode AE13 are removed.

As a result, a third light emitting element ED13 may be formed, the third inorganic layer 171-3 may be spaced apart from the second inorganic layer 171-2, and the third cathode electrode CE13 and the third electrode pattern CEP3 may be completely covered by the third inorganic layer 171-3. In addition, a cavity may be formed between a portion of the second bank layer 163 and the third inorganic layer 171-3.

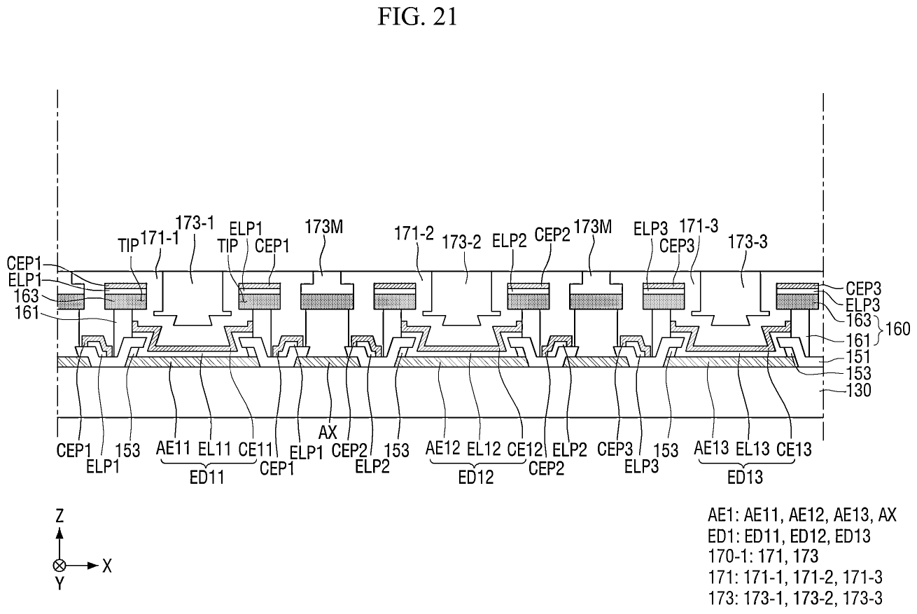

Next, referring to FIG. 21, a second encapsulation layer 173 for planarizing the level difference of an upper surface of the first encapsulation layer 171 is applied to overlap each of the first light emitting element ED11, the second light emitting element ED12, and the third light emitting element ED13. The second encapsulation layer 173 may overlap and be spaced apart from each of the first light emitting element ED11, the second light emitting element ED12, and the third light emitting element ED13. The second encapsulation layer 173 may include a first organic layer 173-1 overlapping the first light emitting element ED11, a second organic layer 173-2 overlapping the second light emitting element ED12, and a third organic layer 173-3 overlapping the third light emitting element ED13.

In addition, in such a process, a monomer pattern material layer 173M may fill a cavity between the first inorganic layer 171-1 and the second inorganic layer 171-2, and a cavity between the second inorganic layer 171-2 and the third inorganic layer 171-3. In other words, the cavity between the first inorganic layer 171-1 and the second inorganic layer 171-2 and the cavity between the second inorganic layer 171-2 and the third inorganic layer 171-3 may be filled and planarized by the monomer pattern material layer 173M. The monomer pattern material layer 173M may include the same material as the second encapsulation layer 173.

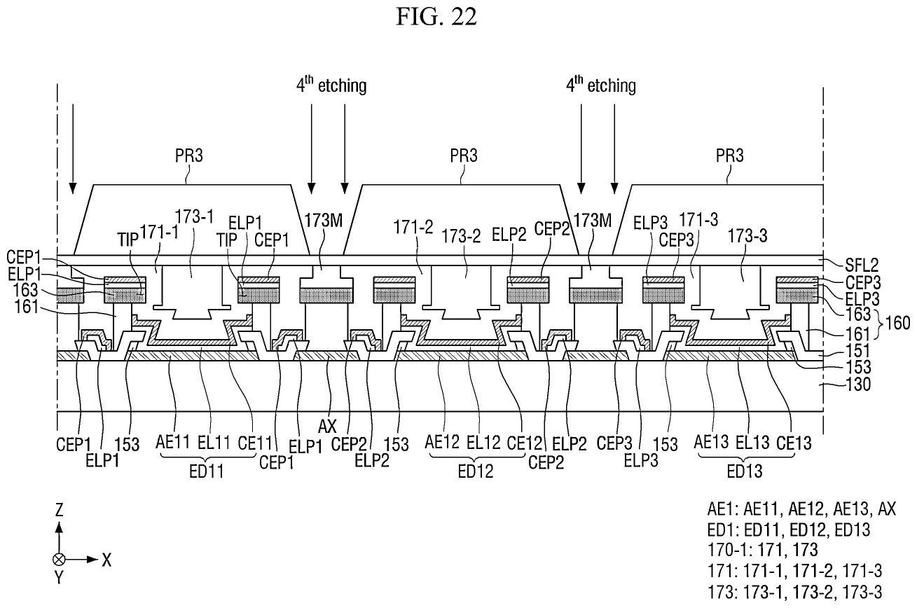

Next, referring to FIG. 22, a sacrificial layer SFL2 is formed on the entirety of the first encapsulation layer 171 and the second encapsulation layer 173, a photoresist PR3 is formed on the sacrificial layer SFL2 to overlap the first light emitting element ED11, the second light emitting element ED12, and the third light emitting element ED13, respectively, and then a fourth etching process is performed. The photoresist PR3 according to an embodiment may be formed to be spaced apart from a portion overlapping the monomer pattern material layer 173M.

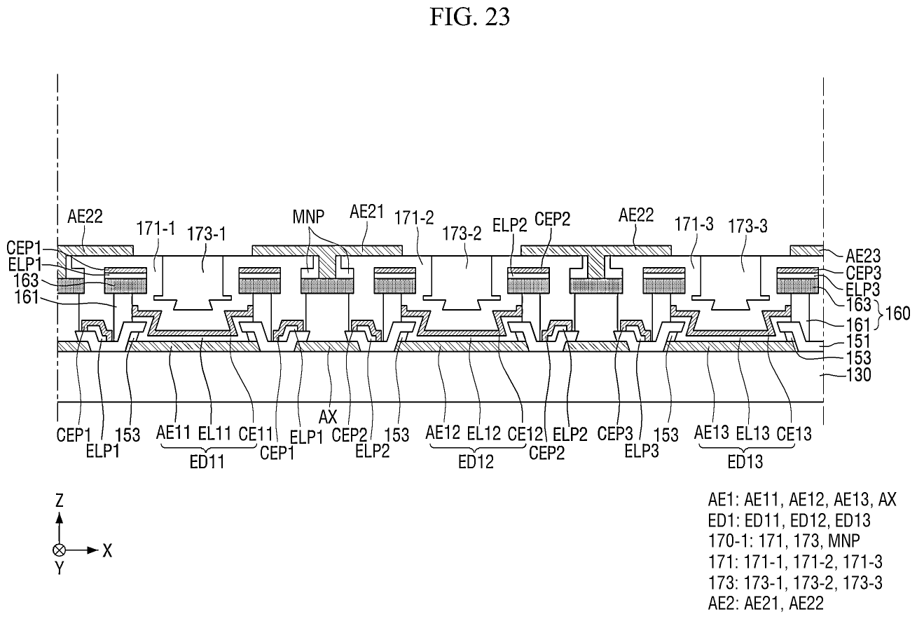

As illustrated in FIG. 23, through such a process, the second bank layer 163 of the bank structure 160 that is not in contact with each of the first light emitting element ED11, the second light emitting element ED12, and the third light emitting element ED13 may be exposed, and a portion of the monomer pattern material layer 173M that is not etched may remain as a monomer pattern MNP.

Next, referring to FIG. 23, a third electrode AE2 is formed to be in contact with the second bank layer 163 exposed in the previous process. The third electrode AE2 may include a first anode electrode AE21, a second anode electrode AE22, and a third anode electrode AE23. The first anode electrode AE21, the second anode electrode AE22, and the third anode electrode AE23, may be spaced apart from each other on the first encapsulation layer 171 and the second encapsulation layer 173.

In such a process, each of the first anode electrode AE21, the second anode electrode AE22, and the third anode electrode AE23 is formed to be in contact with the second bank layer 163, and the third electrode AE2 may be electrically connected to the second bank layer 163, the first bank layer 161, and the first electrode AE1.

Next, referring to FIG. 24, a sacrificial layer SFL3 is formed on each of the first anode electrode AE21, the second anode electrode AE22, and the third anode electrode AE23, and a second pixel defining layer 155 covering a portion of each of the first anode electrode AE21, the second anode electrode AE22, and the third anode electrode AE23 is formed. The second pixel defining layer 155 may separate and insulate the first anode electrode AE21, the second anode electrode AE22, and the third anode electrode AE23 from each other.

The second pixel defining layer 155 according to an embodiment may be formed in a portion that overlaps each of the first light emitting element ED11, the second light emitting element ED12, and the third light emitting element ED13 in the third direction (Z-axis direction). As well, the second pixel defining layer 155 according to an embodiment may be formed in a portion that overlaps each of the first organic layer 173-1, the second organic layer 173-2, and the third organic layer 173-3 in the third direction (Z-axis direction).

As illustrated in FIG. 24, the second pixel defining layer 155 and the spacer 156 may be disposed on a central portion of the sacrificial layer SFL3 overlapping the second anode electrode AE22. The spacer 156 may be disposed to overlap the auxiliary electrode AX and the bank structure 160 in the third direction (Z-axis direction).

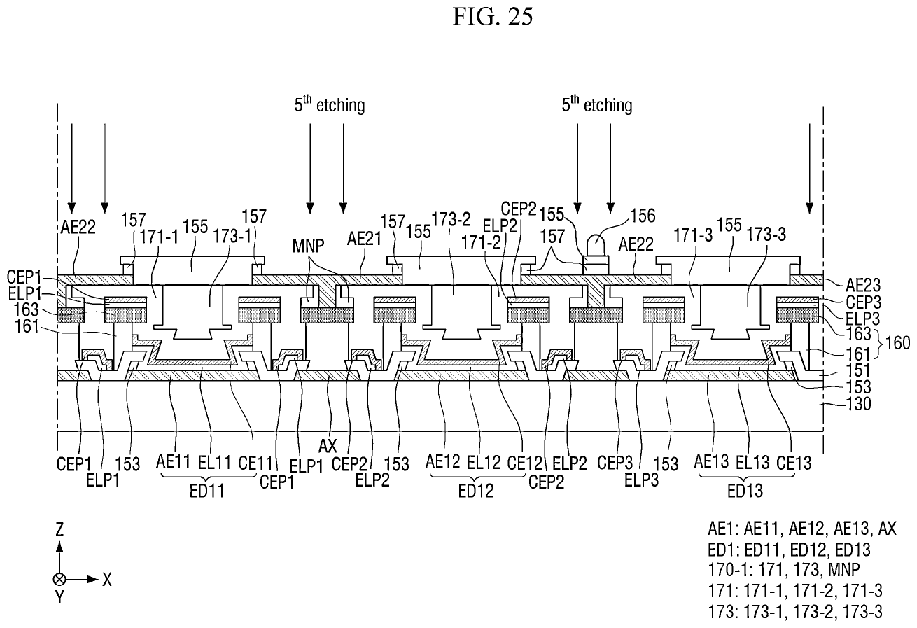

Next, referring to FIG. 25, a fifth etching process for removing the sacrificial layer SFL3 disposed on each of the first anode electrode AE21, the second anode electrode AE22, and the third anode electrode AE23 using the second pixel defining layer 155 as a mask is performed. The sacrificial layer SFL3 according to an embodiment may include an oxide semiconductor. As an example, the fifth etching process may be performed as a wet etching process.

In such a process, a portion of the sacrificial layer SFL3 disposed on each of the first anode electrode AE21, the second anode electrode AE22, and the third anode electrode AE23 may be removed, and a portion of the sacrificial layer SFL3 that is not removed and remains may be disposed as the residual pattern 157 between the third electrode AE2 and the second pixel defining layer 155.

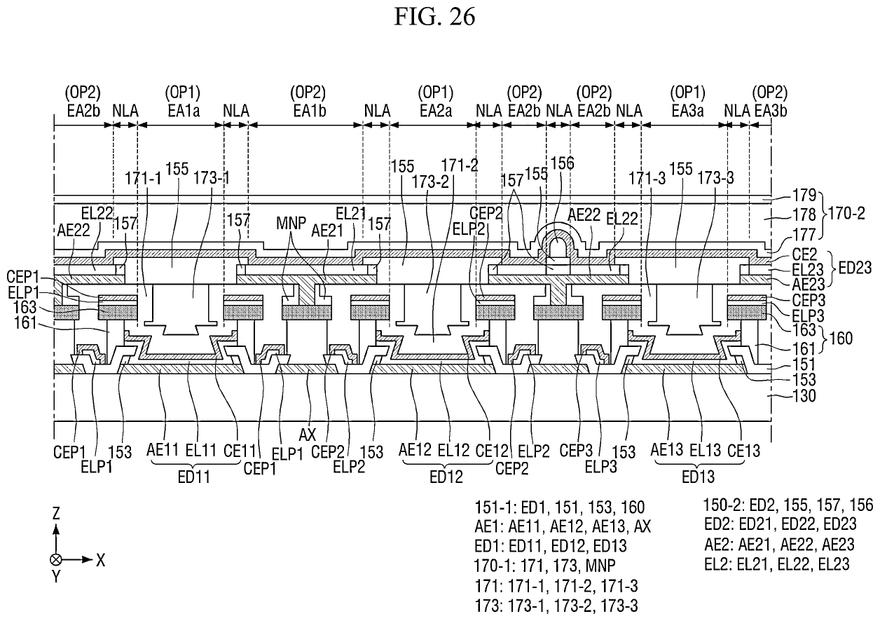

Next, referring to FIG. 26, a second display light emitting layer EL2 is formed on the third electrode AE2, and then a common electrode CE2 entirely covering the second display light emitting layer EL2, the second pixel defining layer 155, and the spacer 156 is formed. Next, the display element layer 150 illustrated in FIG. 6 may be formed by forming a second thin film encapsulation layer 170-2 covering the common electrode CE2.

In such a process, the second display light emitting layer EL2 may be fabricated through a deposition process using a fine metal mask, and in this case, the spacer 156 may assist in preventing the lower structure from being damaged by the fine metal mask. In addition, in such a process, the second display light emitting layer EL2 may be formed to be in contact with the residual pattern 157.

As illustrated in FIG. 26, the first light emitting portion EA1a of the first light emitting area EA1, the first light emitting portion EA2a of the second light emitting area EA2, and the first light emitting portion EA3a of the third light emitting area EA3 according to an embodiment may be defined by the first pixel defining layer 151, and the second light emitting portion EA1b of the first light emitting area EA1, the second light emitting portion EA2b of the second light emitting area EA2, and the second light emitting portion EA3b of the third light emitting area EA3 may be defined by the second pixel defining layer 155. That is, the display device 10 according to an embodiment may maximize an area of the light emitting area and minimize an area of the non-light emitting area by including the first light emitting structure 150-1 and the second light emitting structure 150-2 including different light emitting areas. Therefore, the display device 10 according to an embodiment may have features of high aperture ratio and high resolution.

In concluding the detailed description, those skilled in the art will appreciate that many variations and modifications can be made to the example embodiments without substantially departing from the principles disclosed herein. Therefore, the example embodiments are used in a generic and descriptive sense only and not for purposes of limitation.

What is claimed is:

1. A display device comprising:
a substrate including a light emitting area including a first light emitting portion and a second light emitting portion and a non-light emitting area positioned between the first light emitting portion and the second light emitting portion;
a first light emitting structure including a first display element positioned on the first light emitting portion of the substrate;
a first thin film encapsulation layer on the first light emitting structure; and
a second light emitting structure positioned on the first thin film encapsulation layer and including a second display element overlapping the second light emitting portion,
wherein the first light emitting structure includes a first pixel defining layer defining a first opening; and
a bank structure positioned on the first pixel defining layer and including a first bank layer and a second bank layer,
the second bank layer includes a tip that protrudes more toward the first light emitting portion than a side surface of the first bank layer, and
the second display element overlaps the first pixel defining layer in a direction perpendicular to the substrate and is in contact with the second bank layer.

2. The display device of claim 1, wherein the first display element includes a first electrode; a first display light emitting layer on the first electrode; and a second electrode on the first display light emitting layer,
the first display light emitting layer and the second electrode are in contact with the side surface of the first bank layer facing the first light emitting portion, and
the second electrode is electrically connected to the first bank layer.

3. The display device of claim 2, further comprising a first organic pattern disposed on the second bank layer and surrounding the first opening; and a first electrode pattern disposed on the first organic pattern,
wherein the first organic pattern includes the same material as the first electrode, and
the first electrode pattern includes the same material as the second electrode.

4. The display device of claim 3, wherein the first organic pattern is spaced apart from the first electrode, and the first electrode pattern is spaced apart from the second electrode.

5. The display device of claim 2, wherein in a portion overlapping the non-light emitting area, a first pattern is positioned between the first electrode and the first pixel defining layer in the direction perpendicular to the substrate, and
the first pattern is in contact with the first display light emitting layer.

6. The display device of claim 1, wherein the second light emitting structure further includes a second pixel defining layer overlapping the first light emitting portion and defining a second opening, and
the second pixel defining layer overlaps the first display element in the direction perpendicular to the substrate.

7. The display device of claim 6, wherein the second display element includes a third electrode; a second display light emitting layer on the third electrode; and a common electrode on the second display light emitting layer and the second pixel defining layer.

8. The display device of claim 7, wherein the third electrode is in contact with the second bank layer in a direction toward the substrate.

9. The display device of claim 7, wherein the first thin film encapsulation layer includes:
a first encapsulation layer in contact with the first display element and the bank structure; and
a second encapsulation layer including an organic material on the first encapsulation layer, and
the second encapsulation layer is completely surrounded by the first encapsulation layer and the second pixel defining layer in a portion overlapping the first light emitting portion.

10. The display device of claim 9, further comprising, in a portion overlapping the second light emitting portion, a monomer pattern on side surfaces of the third electrode in a direction parallel to the substrate,
wherein the monomer pattern and the second encapsulation layer include the same material.

11. The display device of claim 9, wherein the first encapsulation layer is in contact with the protruding tip of the second bank layer.

12. The display device of claim 7, wherein in a portion overlapping the non-light emitting area, a second pattern is positioned between the third electrode and the second pixel defining layer in the direction perpendicular to the substrate, and
the second pattern is in contact with the second display light emitting layer.

13. The display device of claim 6, wherein the first opening defines the first light emitting portion, and
the second opening defines the second light emitting portion.

14. The display device of claim 13, wherein in plan view, the first pixel defining layer has a mesh shape that completely surrounds the first light emitting portion, and
in plan view, the second pixel defining layer has a mesh shape that completely surrounds the second light emitting portion.

15. The display device of claim 7, further comprising a spacer disposed on the second pixel defining layer,
wherein the spacer overlaps the third electrode in the direction perpendicular to the substrate.

16. The display device of claim 15, wherein a third pattern is positioned between the spacer and the third electrode in the direction perpendicular to the substrate.

17. A display device comprising:
a substrate including a first light emitting area including a first light emitting portion and a second light emitting portion, and a second light emitting area spaced apart from the second light emitting portion with the first light emitting portion interposed therebetween;
a first light emitting structure positioned on the substrate and including a first light emitting element overlapping the first light emitting portion, a second light emitting element overlapping the second light emitting area, and a bank structure overlapping the second light emitting portion;
a first encapsulation layer on the first light emitting structure; and
a second light emitting structure positioned on the first encapsulation layer and including a third light emitting element overlapping the second light emitting portion,
wherein the bank structure includes a first portion in contact with the first light emitting element, a second portion in contact with the third light emitting element, and a third portion in contact with the second light emitting element, and
the first portion, the second portion, and the third portion are spaced apart from each other with the first encapsulation layer interposed therebetween.

18. The display device of claim 17, wherein the first encapsulation layer includes a first inorganic layer surrounding the first portion; and a second inorganic layer surrounding the third portion, and
the first inorganic layer and the second inorganic layer are spaced apart from each other with the second portion interposed in a direction parallel to the substrate.

19. A method of fabricating a display device, the method comprising:
preparing a substrate including a light emitting area including a first light emitting portion and a second light emitting portion and a non-light emitting area positioned between the first light emitting portion and the second light emitting portion;
forming a first electrode on the first light emitting portion of the substrate and a sacrificial layer on the first electrode, forming an auxiliary electrode spaced apart from the first electrode on the second light emitting portion of the substrate, and forming a first pixel defining layer covering a portion of the sacrificial layer and the auxiliary electrode;
forming a first hole overlapping the first electrode by forming a first bank material layer completely covering the first electrode, the auxiliary electrode, and the first pixel defining layer, and a second bank material layer on the first bank material layer, and then removing a portion of the first bank material layer and the second bank material layer through an etching process;
forming a first bank layer and a second bank layer including a tip protruding more toward the first light emitting portion than the first bank layer by partially etching the inside of the first hole through an etching process, and forming a second hole overlapping the first pixel defining layer;
forming a first light emitting layer and a second electrode on the first electrode overlapping the first light emitting part to be in contact with a side surface of the first bank layer, and forming a first thin film encapsulation layer completely covering the first bank layer and the second bank layer;
exposing a portion of the second bank layer overlapping the second light emitting portion by removing a portion of the first thin film encapsulation layer overlapping the second light emitting portion through an etching process;
forming a third electrode on the second bank layer and the first thin film encapsulation layer and a sacrificial layer on the third electrode to overlap the second light emitting portion, and forming a second pixel defining layer overlapping the first light emitting portion, covering a portion of the sacrificial layer, and defining a second opening;
removing the sacrificial layer on the third electrode through an etching process using the second pixel defining layer as a mask, forming a second light emitting layer on the third electrode, and then forming a common electrode entirely covering the second light emitting layer and the second pixel defining layer; and
forming a second thin film encapsulation layer on the common electrode,
wherein in the forming of the third electrode, the third electrode is in contact with the second bank layer.

20. The method of claim 19, wherein in the forming of the first light emitting layer and the second electrode, a first organic pattern disposed on the second bank layer and a first electrode on the first organic pattern are formed,
the first organic pattern includes the same material as the first light emitting layer, and is spaced apart from the first light emitting layer, and
the first electrode pattern includes the same material as the second electrode, and is spaced apart from the second electrode.
